(19) United States
(12) Patent Application Publication
(10) Pub. No.: US 2024/0284753 A1
(43) Pub. Date: Aug. 22, 2024

(54) SENSING PART AND DISPLAY DEVICE INCLUDING THE SAME

(71) Applicant: Samsung Display Co., Ltd., Yongin-si (KR)

(72) Inventors: CHEOL-GON LEE, Yongin-si (KR); HEERIM SONG, Yongin-si (KR); MUKYUNG JEON, Yongin-si (KR)

(21) Appl. No.: 18/523,428

(22) Filed: Nov. 29, 2023

(30) Foreign Application Priority Data
Feb. 20, 2023 (KR) 10-2023-0022068

(51) Int. Cl. H10K 59/65; G06V 40/13; H10K 59/123; H10K 59/40

(52) U.S. Cl. CPC H10K 59/65; G06V 40/1318; H10K 59/123; H10K 59/40

(57) ABSTRACT

A display device includes: a first pixel unit including a first sensor; and a second pixel unit including a second sensor. The first sensor includes: a first light receiving element; a first-first transistor connected to the first light receiving element; and a first connecting electrode connecting the first light receiving element to the first-first transistor, and extending in a first direction from a first connection point with the first light receiving element. The second sensor includes: a second light receiving element; a first-second transistor connected to the second light receiving element; and a second connecting electrode connecting the second light receiving element to the first-second transistor, and extending in the first direction and a direction opposite to the first direction from a second connection point with the second light receiving element.

### CROSS-REFERENCE TO RELATED APPLICATIONS

This application claims priority to and the benefit of Korean Patent Application No. 10-2023-0022068, filed on Feb. 20, 2023, in the Korean Intellectual Property Office, the entire disclosure of which is incorporated by reference herein.

### BACKGROUND

Aspects of embodiments of the present disclosure relate to a sensing part, and a display device including the same.

Electronic devices, such as a smart phone, a digital camera, a notebook computer, a car navigation unit, a smart television, and the like, which provide an image to a user, include a display device for displaying the image. The display device includes a display panel for generating an image, an input device such as an input sensing part, a camera for taking an external image, and various sensors.

The input sensing part is disposed on the display panel, and senses a touch of a user. The input sensing part may be manufactured as a separate panel, and disposed on the display panel. The sensors may include a fingerprint sensor, a proximity sensor, and an illuminance sensor. From among the sensors, the fingerprint sensor senses a fingerprint on the display panel. The fingerprint sensor is manufactured as a separate module, and disposed in the display device.

The above information disclosed in this Background section is for enhancement of understanding of the background of the present disclosure, and therefore, it may contain information that does not constitute prior art.

### SUMMARY

Embodiments of the present disclosure are directed to a sensing part having improved accuracy for fingerprint sensing, and a display device including the sensing part.

According to one or more embodiments of the present disclosure, a display device includes: a first pixel unit including a first sensor; and a second pixel unit including a second sensor. The first sensor includes: a first light receiving element; a first-first transistor connected to the first light receiving element; and a first connecting electrode connecting the first light receiving element to the first-first transistor, and extending in a first direction from a first connection point with the first light receiving element. The second sensor includes: a second light receiving element; a first-second transistor connected to the second light receiving element; and a second connecting electrode connecting the second light receiving element to the first-second transistor, and extending in the first direction and a direction opposite to the first direction from a second connection point with the second light receiving element.

In an embodiment, a length of the first connecting electrode and a length of the second connecting electrode may be equal to each other.

In an embodiment, a length of the first connecting electrode and a length of the second connecting electrode may be different from each other.

In an embodiment, the first light receiving element may include: a first-first electrode connected to a gate electrode of the first-first transistor through the first connecting electrode; a second electrode over the first-first electrode; and a first light receiving layer between the first-first electrode and the second electrode of the first light receiving element. The second light receiving element may include: a first-second electrode connected to a gate electrode of the first-second transistor through the second connecting electrode; a second electrode over the first-second electrode; and a second light receiving layer between the first-second electrode and the second electrode of the second light receiving element.

In an embodiment, in a second direction crossing the first direction, a distance between the first connection point and the first light receiving layer may be smaller than a distance between the second connection point and the second light receiving layer.

In an embodiment, the first-first electrode may extend from the first light receiving layer in the second direction, and may further extend in the second direction than the first connection point.

In an embodiment, the first-second electrode may extend in the second direction, and may extend from the second light receiving layer to the second connection point.

In an embodiment, a length of the first-first electrode and a length of the first-second electrode may be equal to each other.

In an embodiment, a length of the first-first electrode and a length of the first-second electrode may be different from each other.

In an embodiment, the first-first electrode may further extend from the first light receiving layer in a direction opposite to the second direction.

In an embodiment, the first-first electrode may further extend from the first light receiving layer in the first direction.

In an embodiment, the first-first electrode may further extend from the first light receiving layer in the direction opposite to the first direction.

In an embodiment, portions of the first-first electrode extending from the first light receiving layer in the first direction, the second direction, the direction opposite to the first direction, and the direction opposite to the second direction may have the same width as each other.

In an embodiment, the first pixel unit and the second pixel unit may be located along a first diagonal direction, and the first diagonal direction may cross the first direction and a second direction crossing the first direction on a plane defined by the first direction and the second direction.

In an embodiment, the first pixel unit may further include: a third-first light emitting element; a second-first light emitting element; a first-first light emitting element; and a second-second light emitting element configured to display the same color as that of the second-first light emitting element. The third-first light emitting element, the second-first light emitting element, the first-first light emitting element, and the second-second light emitting element may be sequentially located along the second direction, and the first light receiving element may be adjacent to the second-first light emitting element in the first direction.

In an embodiment, the second pixel unit may include: a third-second light emitting element; a second-third light emitting element; a first-second light emitting element; and a second-fourth light emitting element configured to display the same color as that of the second-third light emitting element. The third-second light emitting element, the second-third light emitting element, the first-second light emitting element, and the second-fourth light emitting element may be sequentially located along the second direction. The first-first light emitting element and the third-second light emitting element may be located along the first direction; the second-second light emitting element and the second-third light emitting element may be located along the first direction; and the second light receiving element may be located between the second-second light emitting element and the second-third light emitting element.

In an embodiment, the first-first transistor may be spaced from the second-first light emitting element in the first direction, and the first-second transistor may be spaced from the second-fourth light emitting element in the first direction.

According to one or more embodiments of the present disclosure, a sensing part includes: a first sensor; and a second sensor located along a diagonal direction with the first sensor. The first sensor includes: a first light receiving element; a first-first transistor connected to the first light receiving element; and a first connecting electrode connecting the first light receiving element to the first-first transistor, and extending in a first direction from a first connection point with the first light receiving element. The second sensor includes: a second light receiving element; a first-second transistor connected to the second light receiving element; and a second connecting electrode connecting the second light receiving element to the first-second transistor, and extending in the first direction and a direction opposite to the first direction from a second connection point with the second light receiving element.

According to one or more embodiments of the present disclosure, a display device includes: a plurality of pixels; and a first sensor and a second sensor located between the pixels. The first sensor includes: a first light receiving element; a first-first transistor; and a first connecting electrode connecting the first light receiving element to the first-first transistor, and extending in a first direction. The second sensor includes: a second light receiving element; a first-second transistor; and a second connecting electrode connecting the second light receiving element to the first-second transistor, and extending in the first direction. The first light receiving element includes: a first-first electrode; a second electrode; and a first light receiving layer between the first-first electrode and the second electrode of the first light receiving element. The second light receiving element includes: a first-second electrode; a second electrode; and a second light receiving layer between the first-second electrode and the second electrode of the second light receiving element. The first-first electrode extends from the first light receiving layer in a second direction crossing the first direction, and further extends in the second direction than the first connecting electrode and a first connection point of the first-first electrode.

In an embodiment, the first-second electrode may extend from the second light receiving layer to the second connecting electrode and a second connection point of the first-second electrode in the second direction, and a length of the first-first electrode may be equal to a length of the first-second electrode.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a perspective view of a display device according to an embodiment of the present disclosure.

FIG. 2 is a sectional view of the display device illustrated in FIG. 1.

FIG. 3 is a sectional view of a display panel illustrated in FIG. 2.

FIG. 4 is a plan view of the display panel illustrated in FIG. 2.

FIG. 5 illustrates an equivalent circuit diagram of one pixel from among the pixels illustrated in FIG. 4, and a sensor adjacent to the pixel.

FIG. 6 is a sectional view illustrating a light emitting element, a first transistor, a fourth transistor, and a sixth transistor of the pixel illustrated in FIG. 5.

FIG. 7 is a sectional view illustrating a light receiving element, a first transistor, and a second transistor of the sensor illustrated in FIG. 5.

FIG. 8 is a sectional view illustrating a fingerprint sensing state by the fingerprint sensor illustrated in FIGS. 5 and 7.

FIG. 9 is a view illustrating a planar arrangement state of the light emitting elements and the light receiving elements disposed in a partial area of the display region illustrated in FIG. 4.

FIGS. 10A-10J are views illustrating planar structures of some of the pixels and some of the sensors illustrated in FIG. 9 in stages.

FIG. 11 is a view illustrating a first light receiving element and a second light receiving element disposed in a planar region larger than that of the layout illustrated in FIG. 10J.

FIGS. 12-14 are views illustrating configurations of first-first electrodes according to embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

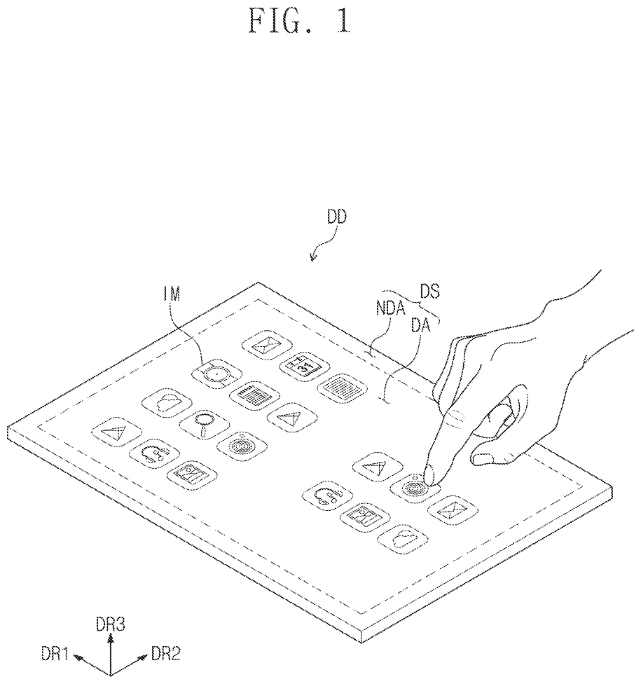

FIG. 1 is a perspective view of a display device according to an embodiment of the present disclosure.

Referring to FIG. 1, the display device DD according to an embodiment of the present disclosure may have a rectangular shape with long sides extending in a first direction DR1, and short sides extending in a second direction DR2 crossing the first direction DR1. However, the present disclosure is not limited thereto, and the display device DD may have various suitable shapes, such as a circular shape, a polygonal shape, and/or the like.

Hereinafter, a direction vertically or substantially vertically crossing a plane defined by the first direction DR1 and the second direction DR2 is defined as a third direction DR3. As used herein, the expressions “when viewed from above the plane” and “in a plan view” may mean a view of an object portion in the third direction DR3.

An upper surface of the display device DD may be defined as a display surface DS, and may have a plane defined by the first direction DR1 and the second direction DR2. Images IM generated by the display device DD may be provided to a user through the display surface DS.

The display surface DS may include a display region DA, and a non-display region NDA around (e.g., adjacent to) the display region DA. The display region DA may display an image, and the non-display region NDA may not display an image. The non-display region NDA may surround (e.g., around a periphery of) the display region DA, and may define a border of the display device DD that may be printed in a suitable color (e.g., a predetermined color).

The display device DD may be used in large electronic devices, such as a television, a monitor, or a billboard. In addition, the display device DD may be used in small-sized and medium-sized electronic devices, such as a personal computer, a notebook computer, a personal digital terminal, a car navigation unit (e.g., a car navigator or navigation device), a game machine, a smart phone, a tablet computer, or a camera. However, the present disclosure is not limited thereto, and the display device DD may be used in various other suitable electronic devices without departing from the spirit and scope of the present disclosure.

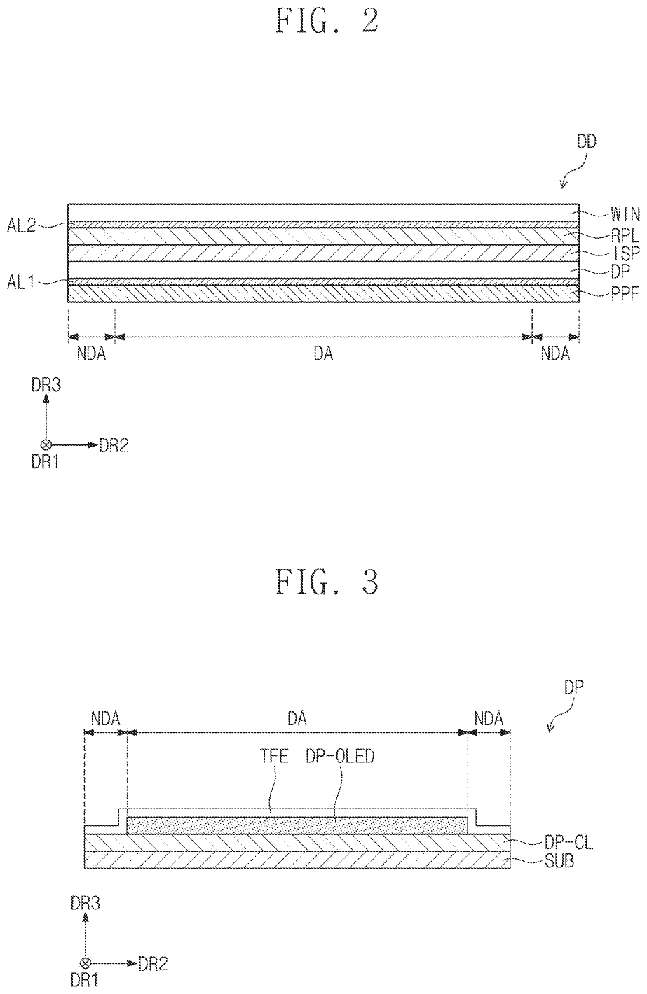

FIG. 2 is a sectional view of the display device illustrated in FIG. 1.

In FIG. 2, a section (e.g., a cross-section) of the display device DD viewed in the first direction DR1 is illustrated.

Referring to FIG. 2, the display device DD may include a display panel DP, an input sensing part (e.g., an input sensing layer or panel) ISP, an anti-reflection layer RPL, a window WIN, a panel protection film PPF, and first and second adhesive layers AL1 and AL2.

The display panel DP may be a flexible display panel. The display panel DP according to an embodiment of the present disclosure may be an emissive display panel, but is not particularly limited thereto. For example, the display panel DP may be an organic light emitting display panel or an inorganic light emitting display panel. An emissive layer of the organic light emitting display panel may include an organic light emitting material. An emissive layer of the inorganic light emitting display panel may include quantum dots, quantum rods, and/or the like. Hereinafter, for convenience, the display panel DP may be described in more detail in the context of an organic light emitting display panel, but the present disclosure is not limited thereto.

The input sensing part ISP may be disposed on the display panel DP. The input sensing part ISP may include a plurality of sensing parts for sensing an external input in a capacitive manner. The input sensing part ISP may be directly manufactured on the display panel DP when the display device DD is manufactured. However, the present disclosure is not limited thereto, and the input sensing part ISP may be manufactured as a panel separate from the display panel DP, and may be attached to the display panel DP by an adhesive layer.

The anti-reflection layer RPL may be disposed on the input sensing part ISP. The anti-reflection layer RPL may be directly manufactured on the input sensing part ISP when the display device DD is manufactured. However, the present disclosure is not limited thereto, and the anti-reflection layer RPL may be manufactured as a separate panel, and may be attached to the input sensing part ISP by an adhesive layer.

The anti-reflection layer RPL may be defined as a film for preventing or substantially preventing reflection of external light. The anti-reflection layer RPL may decrease the reflectance of external light that is incident toward the display panel DP from above the display device DD. Due to the anti-reflection layer RPL, the external light may not be visible to the user.

When external light travelling toward the display panel DP is reflected from the display panel DP and provided back to the user, the user may visually recognize the external light as in a mirror. To prevent or substantially prevent such a phenomenon, the anti-reflection layer RPL may include a plurality of color filters that display the same colors as those of the pixels of the display panel DP.

The color filters may filter external light into the same colors as those of the pixels. In this case, the external light may not be visible to the user. However, the present disclosure is not limited thereto, and the anti-reflection layer RPL may include a phase retarder and/or a polarizer to decrease the reflectance of the external light.

The window WIN may be disposed on the anti-reflection layer RPL. The window WIN may protect the display panel DP, the input sensing part ISP, and the anti-reflection layer RPL from external scratches and impacts.

The panel protection film PPF may be disposed under the display panel DP. The panel protection film PPF may protect the bottom of the display panel DP. The panel protection film PPF may include a flexible plastic material, such as polyethylene terephthalate (PET).

The first adhesive layer AL1 may be disposed between the display panel DP and the panel protection film PPF, and the display panel DP and the panel protection film PPF may be connected to (e.g., bonded to or attached to) each other by the first adhesive layer AL1. The second adhesive layer AL2 may be disposed between the window WIN and the anti-reflection layer RPL, and the window WIN and the anti-reflection layer RPL may be connected to (e.g., bonded to or attached to) each other by the second adhesive layer AL2.

FIG. 3 is a sectional view of the display panel illustrated in FIG. 2.

In FIG. 3, a section (e.g., a cross-section) of the display panel DP viewed in the first direction DR1 is illustrated.

Referring to FIG. 3, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include a display region DA, and a non-display region NDA around (e.g., adjacent to) the display region DA. The substrate SUB may include a flexible plastic material, such as glass or polyimide (PI). The display element layer DP-OLED may be disposed on the display region DA.

A plurality of pixels may be disposed in the circuit element layer DP-CL and the display element layer DP-OLED. Each of the pixels may include a transistor disposed in the circuit element layer DP-CL, and a light emitting element disposed in the display element layer DP-OLED and connected to the transistor.

The thin film encapsulation layer TFE may be disposed on the circuit element layer DP-CL to cover the display element layer DP-OLED. The thin film encapsulation layer TFE may protect the pixels from moisture, oxygen, and external foreign matters.

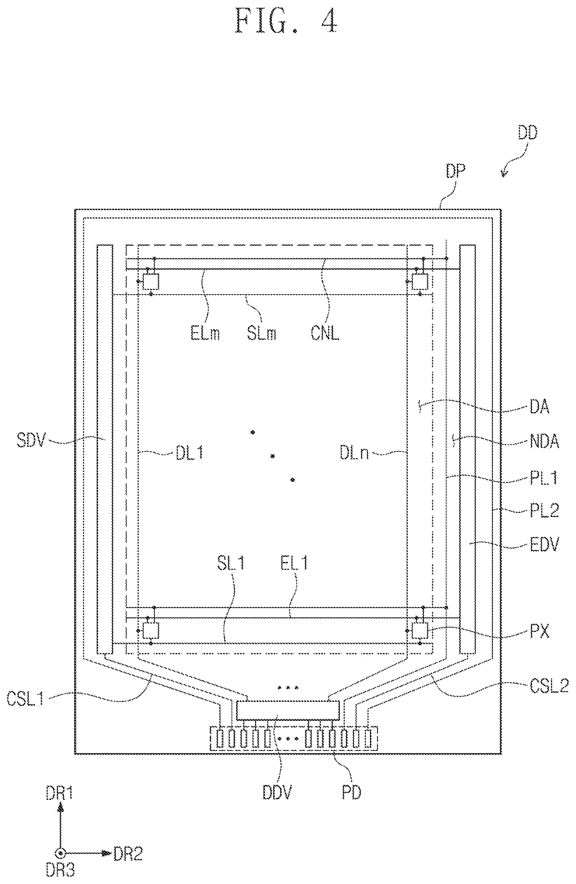

FIG. 4 is a plan view of the display panel illustrated in FIG. 2.

Referring to FIG. 4, the display device DD may include the display panel DP, a scan driver SDV, a data driver DDV, a light emission driver EDV, and a plurality of pads PD.

The display panel DP may have a rectangular shape with long sides extending in the first direction DR1, and short sides extending in the second direction DR2. However, the shape of the display panel DP is not limited thereto. The display panel DP may include the display region DA, and the non-display region NDA surrounding (e.g., around a periphery of) the display region DA.

The display panel DP may include the plurality of pixels PX, a plurality of scan lines SL1 to SLm, a plurality of data lines DL1 to DLn, a plurality of light emission lines EL1 to ELm, first and second control lines CSL1 and CSL2, first and second power lines PL1 and PL2, and connecting lines CNL. Here, “m” and “n” are natural numbers.

The display panel DP may further include a sensing part for sensing a fingerprint. In other words, the sensing part for sensing a fingerprint may not be manufactured as a separate module (e.g., a separate circuit or device), but may be imbedded in the display panel DP. The sensing part may include a plurality of sensors disposed between the pixels PX. The positions in which the sensors are disposed will be described in more detail below.

The pixels PX may be disposed in the display region DA. The scan driver SDV and the light emission driver EDV may be disposed in areas of the non-display region NDA adjacent to the long sides of the display panel DP, respectively. The data driver DDV may be disposed in the non-display region NDA adjacent to one of the short sides of the display panel DP. The data driver DDV may be adjacent to a lower end of the display panel DP when viewed from above the plane (e.g., in a plan view).

The scan lines SL1 to SLm may extend in the second direction DR2, and may be connected to the pixels PX and the scan driver SDV. The data lines DL1 to DLn may extend in the first direction DR1, and may be connected to the pixels PX and the data driver DDV. The light emission lines EL1 to ELm may extend in the second direction DR2, and may be connected to the pixels PX and the light emission driver EDV.

The first power line PL1 may extend in the first direction DR1, and may be disposed in the non-display region NDA. The first power line PL1 may be disposed between the display region DA and the light emission driver EDV.

The connecting lines CNL may extend in the second direction DR2, and may be arranged along the first direction DR1. The connecting lines CNL may be connected to the first power line PL1 and the pixels PX. A first voltage may be applied to the pixels PX through the first power line PL1 and the connecting lines CNL that are connected with each other.

The second power line PL2 may be disposed in the non-display region NDA, and may extend along the long sides of the display panel DP and another short side of the display panel DP where the data driver DDV is not disposed. The second power line PL2 may be disposed outward (e.g., at an outer side) of the scan driver SDV and the light emission driver EDV.

In some embodiments, the second power line PL2 may extend toward the display region DA, and may be connected to the pixels PX. A second voltage having a lower level than that of the first voltage may be applied to the pixels PX through the second power line PL2.

The first control line CSL1 may be connected to the scan driver SDV, and may extend toward a lower end of the display panel DP. The second control line CSL2 may be connected to the light emission driver EDV, and may extend toward the lower end of the display panel DP. The data driver DDV may be disposed between the first control line CSL1 and the second control line CSL2.

The pads PD may be disposed in the non-display region NDA adjacent to the lower end of the display panel DP, and may be closer to the lower end of the display panel DP than the data driver DDV. The data driver DDV, the first and second power lines PL1 and PL2, and the first and second control lines CSL1 and CSL2 may be connected to the pads PD. The data lines DL1 to DLn may be connected to the data driver DDV, and the data driver DDV may be connected to the pads PD corresponding to the data lines DL1 to DLn.

In some embodiments, the display device DD may further include a timing controller for controlling operations of the scan driver SDV, the data driver DDV, and the light emission driver EDV, and a voltage generator for generating the first and second voltages. The timing controller and the voltage generator may be mounted on a printed circuit board, and may be connected to the pads PD through the printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The light emission driver EDV may generate a plurality of light emission signals, and the light emission signals may be applied to the pixels PX through the light emission lines EL1 to ELm.

The pixels PX may receive the data voltages in response to the scan signals. The pixels PX may display an image by emitting light having a desired luminance corresponding to the data voltages in response to the light emission signals.

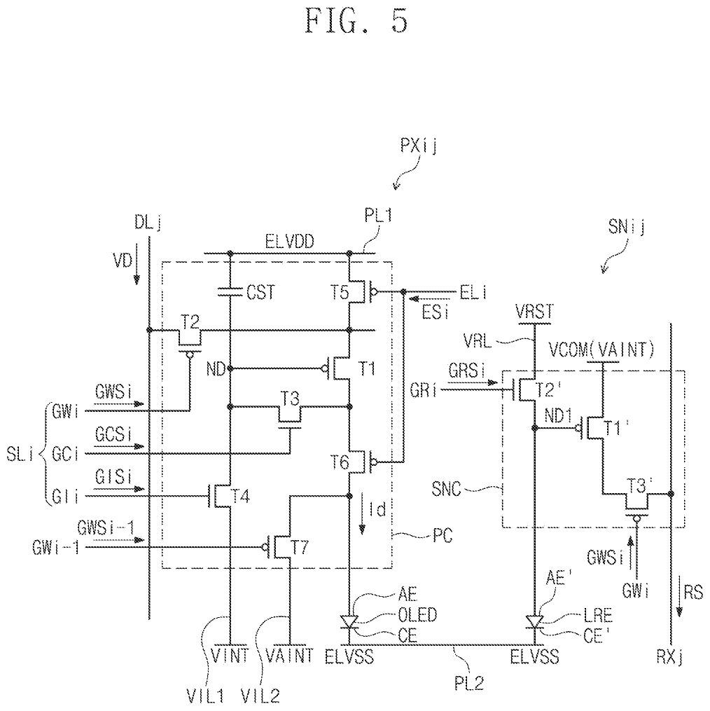

FIG. 5 illustrates an equivalent circuit diagram of one pixel from among the pixels PX illustrated in FIG. 4, and a sensor adjacent to the pixel.

In FIG. 5, the pixel PXij connected to an i-th scan line SLi, an i-th light emission line ELi, and a j-th data line DLj is illustrated as an example. In addition, the sensor SNij connected to an i-th reset line GRi and a j-th receive line RXj is illustrated in FIG. 5. Here, “i” and “j” are natural numbers.

Referring to FIG. 5, the pixel PXij may include a pixel circuit PC, and a light emitting element OLED connected to the pixel circuit PC. The pixel circuit PC may drive the light emitting element OLED.

The pixel circuit PC may include a plurality of transistors T1 to T7, and a capacitor CST. The transistors T1 to T7 and the capacitor CST may control an amount of current flowing through the light emitting element OLED. The light emitting element OLED may generate light having a desired luminance (e.g., a predetermined luminance) depending on the amount of current provided thereto.

The i-th scan line SLi may include the i-th write scan line GWi, the i-th compensation scan line GCi, and the i-th initialization scan line Gli. The i-th write scan line GWi may receive the i-th write scan signal GWSi. The i-th compensation scan line GCi may receive the i-th compensation scan signal GCSi. The i-th initialization scan line Gli may receive the i-th initialization scan signal GISi.

Hereinafter, one of a source electrode and a drain electrode of each of transistors may be referred to as a first electrode, and the other one may be referred to as a second electrode. In addition, a gate electrode of the transistor may be referred to as a control electrode.

The transistors T1 to T7 may include first to seventh transistors T1 to T7. The first, second, fifth, sixth, and seventh transistors T1, T2, T5, T6, and T7 may be PMOS transistors. The third and fourth transistors T3 and T4 may be NMOS transistors. Each of the first to seventh transistors T1 to T7 may include a source electrode, a drain electrode, and a gate electrode.

The light emitting element OLED may be defined as an organic light emitting element. The light emitting element OLED may include an anode AE and a cathode CE. The anode AE may receive a first voltage ELVDD through the sixth, first, and fifth transistors T6, T1, and T5. The cathode CE may be connected to the second power line PL2 that receives a second voltage ELVSS. The cathode CE may receive the second voltage ELVSS.

The first transistor T1 may be connected between the fifth transistor T5 and the sixth transistor T6. The first transistor T1 may include a first electrode that receives the first voltage ELVDD through the fifth transistor T5, a second electrode connected to the anode AE through the sixth transistor T6, and a control electrode connected to a node ND.

The first electrode of the first transistor T1 may be connected to the fifth transistor T5, and the second electrode of the first transistor T1 may be connected to the sixth transistor T6. Depending on a voltage of the node ND applied to the control electrode of the first transistor T1, the first transistor T1 may control the amount of current flowing through the light emitting element OLED.

The second transistor T2 may be connected between the data line DLj and the first electrode of the first transistor T1. The second transistor T2 may include a first electrode connected to the data line DLj, a second electrode connected to the first electrode of the first transistor T1, and a control electrode connected to the i-th write scan line GWi.

The second transistor T2 may be turned on by the i-th write scan signal GWSi applied through the i-th write scan line GWi, and may electrically connect the data line DLj and the first electrode of the first transistor T1. The second transistor T2 may perform a switching operation of providing a data voltage VD applied through the data line DLj to the first electrode of the first transistor T1.

The third transistor T3 may be connected between the second electrode of the first transistor T1 and the node ND. The third transistor T3 may include a first electrode connected to the second electrode of the first transistor T1, a second electrode connected to the node ND, and a control electrode connected to the i-th compensation scan line GCi.

The third transistor T3 may be turned on by the i-th compensation scan signal GCSi applied through the i-th compensation scan line GCi, and may electrically connect the second electrode of the first transistor T1 and the control electrode of the first transistor T1 to each other. When the third transistor T3 is turned on, the first transistor T1 and the third transistor T3 may be connected in a diode form. In other words, the third transistor T3 may diode-connect the first transistor T1.

The fourth transistor T4 may be connected to the node ND. The fourth transistor T4 may include a first electrode connected to the node ND, a second electrode connected to a first initialization line VIL1, and a control electrode connected to the i-th initialization scan line Gli. The fourth transistor T4 may be turned on by the i-th initialization scan signal GISi applied through the i-th initialization scan line Gli, and may provide a first initialization voltage VINT applied through the first initialization line VIL1 to the node ND.

The fifth transistor T5 may include a first electrode connected to the first power line PL1 that receives the first voltage ELVDD, a second electrode connected to the first electrode of the first transistor T1, and a control electrode connected to the i-th light emission line ELi.

The sixth transistor T6 may include a first electrode connected to the second electrode of the first transistor T1, a second electrode connected to the anode AE, and a control electrode connected to the i-th light emission line ELi.

The fifth transistor T5 and the sixth transistor T6 may be turned on by the i-th light emission signal ESi applied through the i-th light emission line ELi. The first voltage ELVDD may be provided to the light emitting element OLED by the turned-on fifth transistor T5 and the turned-on sixth transistor T6, and a drive current may flow through the light emitting element OLED. Accordingly, the light emitting element OLED may emit light.

The seventh transistor T7 may include a first electrode connected to the anode AE, a second electrode connected to a second initialization line VIL2, and a control electrode connected to the (i−1)th write scan line GWi−1. The (i−1)th write scan line GWi−1 may be defined as a write scan line preceding the i-th write scan line GWi.

The seventh transistor T7 may be turned on by the (i−1)th write scan signal GWSi−1 applied through the (i−1)th write scan line GWi−1, and may provide a second initialization voltage VAINT received through the second initialization line VIL2 to the anode AE of the light emitting element OLED.

In an embodiment of the present disclosure, the second initialization voltage VAINT may have a level different from that of the first initialization voltage VINT. However, the present disclosure is not limited thereto, and the second initialization voltage VAINT may have the same or substantially the same level as that of the first initialization voltage VINT

The capacitor CST may include a first electrode that receives the first voltage ELVDD, and a second electrode connected to the node ND. When the fifth transistor T5 and the sixth transistor T6 are turned on, the amount of current flowing through the first transistor T1 may be determined depending on a voltage stored in the capacitor CST.

The display panel DP may include the sensor SNij as well as the pixel PXij. The sensor SNij illustrated in FIG. 5 may be provided in plural numbers (e.g., in a plurality) in the display panel DP to form the aforementioned sensing part.

The sensor SNij may include a sensing circuit SNC, and a light receiving element LRE connected to the sensing circuit SNC. The sensing circuit SNC may drive the light receiving element LRE.

The sensing circuit SNC may include a first transistor T1′, a second transistor T2′, and a third transistor T3′. The first and third transistors T1′ and T3′ may be PMOS transistors, and the second transistor T2′ may be an NMOS transistor.

The first transistor T1′ may be connected to the light receiving element LRE, the second transistor T2′, and the third transistor T3′. The first transistor T1′ may include a first electrode that receives a voltage VCOM having a suitable voltage level (e.g., a predetermined voltage level), a control electrode connected to a node ND1, and a second electrode connected to the third transistor T3′. The first transistor T1′ may be connected to the light receiving element LRE through the node ND1.

For example, the voltage VCOM may be the same or substantially the same as (e.g., may be set to) the second initialization voltage VAINT. However, the present disclosure is not limited thereto, and the voltage VCOM may have (e.g., may be set to) another suitable voltage level.

The second transistor T2′ may include a first electrode connected to the node ND1, a control electrode connected to the i-th reset line GRi, and a second electrode connected to a reset voltage line VRL that receives a reset voltage VRST. The second transistor T2′ may be turned on by the i-th reset signal GRSi received through the i-th reset line GRi.

The third transistor T3′ may include a first electrode connected to the second electrode of the first transistor T1′, a control electrode connected to the i-th write scan line GWi, and a second electrode connected to the receive line RXj. The third transistor T3′ may be turned on by the i-th write scan signal GWSi received through the i-th write scan line GWi.

The light receiving element LRE may include a photo diode. An anode AE′ of the light receiving element LRE may be connected to the node ND1, and a cathode CE′ of the light receiving element LRE may be connected to the second power line PL2 that receives the second voltage ELVSS. The control electrode of the first transistor T1′ may be connected to the anode AE′ of the light receiving element LRE through the node ND1. The light receiving element LRE may convert light energy incident from the outside into electrical energy.

The i-th reset signal GRSi may be applied to the control electrode of the second transistor T2′, and the second transistor T2′ may be turned on accordingly. The turned-on second transistor T2′ may receive the reset voltage VRST, and may provide the reset voltage VRST to the node ND1. The node ND1 may be reset by the reset voltage VRST.

The i-th write scan signal GWSi may be applied to the control electrode of the third transistor T3′, and the third transistor T3′ may be turned on accordingly. The first transistor T1′ may be connected to the receive line RXj by the turned-on third transistor T3′.

The light receiving element LRE may receive light, and may convert the light into an electrical signal. In this case, the voltage of the node ND1 may change. When the first transistor T′ is turned on, the voltage VCOM provided to the first transistor T1 may be controlled depending on the change in the voltage of the node ND1, and may be provided to the receive line RXj through the third transistor T3′. Accordingly, a signal sensed by the light receiving element LRE may be output through the receive line RXj as a sensing signal RS.

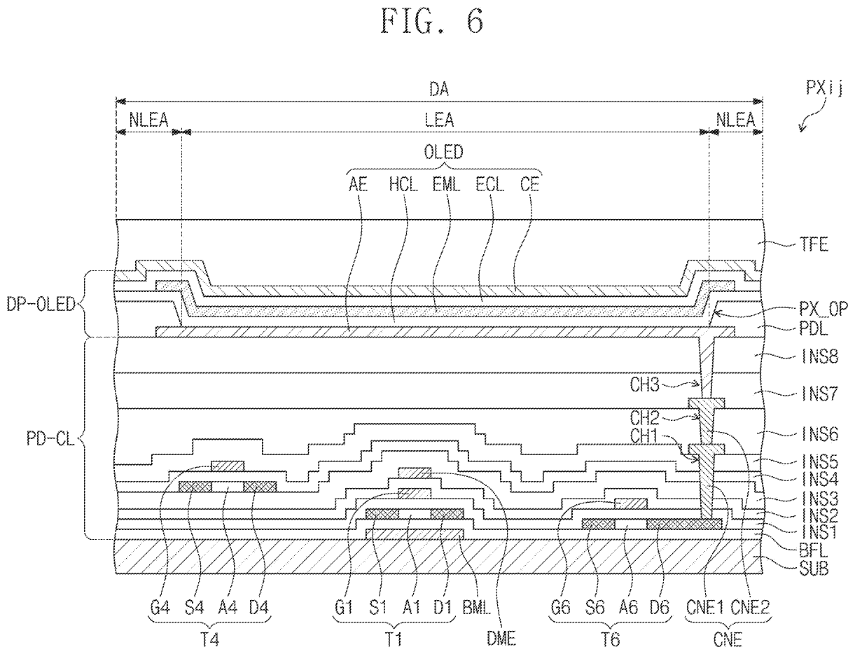

FIG. 6 is a sectional view illustrating the light emitting element, the first transistor, the fourth transistor, and the sixth transistor of the pixel illustrated in FIG. 5.

Referring to FIG. 6, the light emitting element OLED may include a first electrode AE, a second electrode CE, a hole control layer HCL, an electron control layer ECL, and an emissive layer EML. The first electrode AE may be the anode AE illustrated in FIG. 5, and the second electrode CE may be the cathode CE illustrated in FIG. 5. The second electrode CE may be disposed over the first electrode AE, and the hole control layer HCL, the electron control layer ECL, and the emissive layer EML may be disposed between the first electrode AE and the second electrode CE.

The first, fourth, and sixth transistors T1, T4, and T6 and the light emitting element OLED may be disposed on the substrate SUB. The display region DA may include an emissive region LEA corresponding to the pixel PXij, and a non-emissive region NLEA adjacent to the emissive region LEA. The light emitting element OLED may be disposed in the emissive region LEA.

A lower metal layer BML may be disposed on the substrate SUB. The lower metal layer BML may overlap with the first transistor T1. In some embodiments, a constant voltage may be applied to the lower metal layer BML. When the constant voltage is applied to the lower metal layer BML, the threshold voltage Vth of the first transistor T1 that is disposed over the lower metal layer BML may remain unchanged.

Furthermore, the lower metal layer BML may block light incident to the first transistor T1 from below the lower metal layer BML. The lower metal layer BML may include a reflective metal. However, the present disclosure is not limited thereto, and the lower metal layer BML may be omitted as needed or desired.

A buffer layer BFL may be disposed on the substrate SUB. The buffer layer BFL may be an inorganic layer. The buffer layer BFL may cover the lower metal layer BML. A semiconductor layer S1, A1, and D1 of the first transistor T1 and a semiconductor layer S6, A6, and D6 of the sixth transistor T6 may be disposed on the buffer layer BFL. The semiconductor layers S1, A1, D1, S6, A6, and D6 may include poly silicon. However, the present disclosure is not limited thereto, and the semiconductor layers S1, A1, D1, S6, A6, and D6 may include amorphous silicon.

The semiconductor layers S1, A1, D1, S6, A6, and D6 may be doped with an N-type dopant or a P-type dopant. The semiconductor layers S1, A1, D1, S6, A6, and D6 may include heavily doped regions and lightly doped regions. The heavily doped regions may have a higher conductivity than that of the lightly doped regions, and may serve or substantially serve as source electrodes and drain electrodes of the first and sixth transistors T1 and T6. The lightly doped regions may correspond to or substantially correspond to active regions (or channel regions) of the first and sixth transistors T1 and T6.

The first source region S1, the first channel region A1, and the first drain region D1 of the first transistor T1 may be formed from the semiconductor layer S1, A1, and D1. The sixth source region S6, the sixth channel region A6, and the sixth drain region D6 of the sixth transistor T6 may be formed from the semiconductor layer S6, A6, and D6. The first channel region A1 may be disposed between the first source region S1 and the first drain region D1. The sixth channel region A6 may be disposed between the sixth source region S6 and the sixth drain region D6.

A first insulating layer INS1 may be disposed on the buffer layer BFL to cover the semiconductor layers S1, A1, D1, S6, A6, and D6. First and sixth gate electrodes G1 and G6 (e.g., control electrodes) of the first and sixth transistors T1 and T6 may be disposed on the first insulating layer INS1.

In some embodiments, a structure of a source region, a channel region, a drain region, and a gate electrode of each of the second, fifth, and seventh transistors T2, T5, and T7 may be the same or substantially the same as those of the first and sixth transistors T1 and T6 described above.

A second insulating layer INS2 may be disposed on the first insulating layer INS1 to cover the first and sixth gate electrodes G1 and G6. A dummy electrode DME may be disposed on the second insulating layer INS2. The dummy electrode DME may be disposed over the first gate electrode G1. The dummy electrode DME may overlap with the first gate electrode G1 when viewed from above the plane (e.g., in a plan view). The dummy electrode DME may form the above-described capacitor CST together with the first gate electrode G1.

A third insulating layer INS3 may be disposed on the second insulating layer INS2 to cover the dummy electrode DME. A semiconductor layer S4, A4, and D4 of the fourth transistor T4 may be disposed on the third insulating layer INS3. The semiconductor layer S4, A4, and D4 may include an oxide semiconductor formed of a metal oxide. The oxide semiconductor may include a crystalline or amorphous oxide semiconductor.

The semiconductor layer S4, A4, and D4 may include a plurality of regions distinguished from one another depending on whether or not a metal oxide is reduced. A region where the metal oxide is reduced (hereinafter, referred to as the reduced region) has a higher conductivity than that of a region where the metal oxide is not reduced (hereinafter, referred to as the non-reduced region). The reduced region may serve or substantially serve as a source electrode or a drain electrode of the fourth transistor T4. The non-reduced region may correspond to or substantially correspond to an active region (or a channel region) of the fourth transistor T4.

The fourth source region S4, the fourth channel region A4, and the fourth drain region D4 of the fourth transistor T4 may be formed from the semiconductor layer S4, A4, and D4. The fourth channel region A4 may be disposed between the fourth source region S4 and the fourth drain region D4.

A fourth insulating layer INS4 may be disposed on the third insulating layer INS3 to cover the semiconductor layer S4, A4, and D4. A fourth gate electrode G4 of the fourth transistor T4 may be disposed on the fourth insulating layer INS4.

A fifth insulating layer INS5 may be disposed on the fourth insulating layer INS4 to cover the fourth gate electrode G4. In some embodiments, a structure of a source region, a channel region, a drain region, and a gate electrode of the third transistor T3 may be the same or substantially the same as that of the fourth transistor T4 described above.

The buffer layer BFL and the first to fifth insulating layers INS1 to INS5 may include inorganic layers. For example, the buffer layer BFL, the first insulating layer INS1, and the fourth insulating layer INS4 may include a silicon oxide layer, and the second insulating layer INS2 may include a silicon nitride layer.

The third and fifth insulating layers INS3 and INS5 may include different materials from each other, and may include a plurality of inorganic insulating layers stacked one above another. For example, the third insulating layer INS3 may include a silicon nitride layer and a silicon oxide layer that are sequentially stacked, and the fifth insulating layer INS5 may include a silicon oxide layer and a silicon nitride layer that are sequentially stacked. The thicknesses of the third and fifth insulating layers INS3 and INS5 may be greater than the thicknesses of the buffer layer BFL and the first, second, and fourth insulating layers INS1, INS2, and INS4.

A connecting electrode CNE may be disposed between the sixth transistor T6 and the light emitting element OLED. The connecting electrode CNE may electrically connect the sixth transistor T6 and the light emitting element OLED to each other. The connecting electrode CNE may include a first sub-connecting electrode CNE1, and a second sub-connecting electrode CNE2 disposed on the first sub-connecting electrode CNE1.

The first sub-connecting electrode CNE1 may be disposed on the fifth insulating layer INS5, and may be connected to the sixth drain region D6 through a first contact hole CH1 defined in (e.g., penetrating) the first to fifth insulating layers INS1 to INS5. A sixth insulating layer INS6 may be disposed on the fifth insulating layer INS5 to cover the first sub-connecting electrode CNE1.

The second sub-connecting electrode CNE2 may be disposed on the sixth insulating layer INS6. The second sub-connecting electrode CNE2 may be connected to the first sub-connecting electrode CNE1 through a second contact hole CH2 defined in (e.g., penetrating) the sixth insulating layer INS6.

A seventh insulating layer INS7 may be disposed on the sixth insulating layer INS6 to cover the second sub-connecting electrode CNE2. An eighth insulating layer INS8 may be disposed on the seventh insulating layer INS7. The sixth to eighth insulating layers INS6 to INS8 may include an inorganic layer or an organic layer.

The first electrode AE may be disposed on the eighth insulating layer INS8. The first electrode AE may be connected to the second sub-connecting electrode CNE2 through a third contact hole CH3 defined in (e.g., penetrating) the seventh and eighth insulating layers INS7 and INS8.

A pixel defining layer PDL exposing a portion (e.g., a predetermined portion) of the first electrode AE may be disposed on the first electrode AE and the eighth insulating layer INS8. An opening PX-OP for exposing the portion of the first electrode AE may be defined in the pixel defining layer PDL.

The hole control layer HCL may be disposed on the first electrode AE and the pixel defining layer PDL. The hole control layer HCL may be commonly disposed in the emissive region LEA and the non-emissive region NLEA. The hole control layer HCL may include a hole transport layer and/or a hole injection layer.

The emissive layer EML may be disposed on the hole control layer HCL. The emissive layer EML may be disposed in a region corresponding to the opening PX_OP. The emissive layer EML may include an organic material and/or an inorganic material. The emissive layer EML may generate one of red light, green light, or blue light.

The electron control layer ECL may be disposed on the emissive layer EML and the hole control layer HCL. The electron control layer ECL may be commonly disposed in the emissive region LEA and the non-emissive region NLEA. The electron control layer ECL may include an electron transport layer and/or an electron injection layer.

The second electrode CE may be disposed on the electron control layer ECL. The second electrode CE may be commonly disposed for the pixels PX. In other words, the second electrode CE may be commonly disposed over the emissive layers EML of the pixels PX.

The layers from the buffer layer BFL to the eighth insulating layer INS8 may be defined as the circuit element layer DP-CL. The layer in which the light emitting element OLED is disposed may be defined as the display element layer DP-OLED.

The thin film encapsulation layer TFE may be disposed on the light emitting element OLED. The thin film encapsulation layer TFE may include an inorganic layer, an organic layer, and an inorganic layer that are sequentially stacked one above another. The inorganic layers may include an inorganic material, and may protect the pixels PX from moisture/oxygen. The organic layer may include an organic material, and may protect the pixels PX from foreign matter, such as dust particles.

The first voltage ELVDD may be applied to the first electrode AE, and the second voltage EVLSS may be applied to the second electrode CE. Holes and electrons injected into the emissive layer EML may be combined with each other to form excitons, and the light emitting element OLED may emit light as the excitons transition to a ground state. An image may be displayed as the light emitting element OLED emits light.

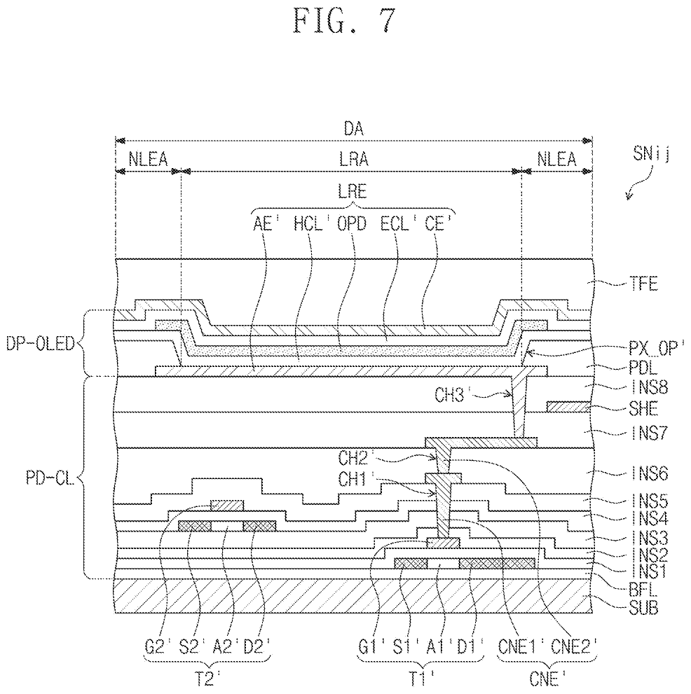

FIG. 7 is a sectional view illustrating the light receiving element, the first transistor, and the second transistor of the sensor illustrated in FIG. 5.

In the following description of the configuration illustrated in FIG. 7, a structure different from the stacked structure illustrated in FIG. 6 may be mainly described.

Referring to FIG. 7, the display region DA may include a light receiving region LRA corresponding to the sensor SNij, and a non-emissive region NLEA adjacent to the light receiving region LRA. The non-emissive region NLEA may correspond to (e.g., may be) the non-emissive region NLEA illustrated in FIG. 6.

The light receiving element LRE may include a first electrode AE′, a second electrode CE′, a hole control layer HCL′, an electron control layer ECL′, and a light receiving layer OPD. The first electrode AE′ may be the anode AE′ illustrated in FIG. 5, and the second electrode CE′ may be the cathode CE′ illustrated in FIG. 5.

The light receiving layer OPD may be defined as an organic photo diode. The first electrode AE′, the second electrode CE′, the hole control layer HCL′, and the electron control layer ECL′ may be the same or substantially the same components as the first electrode AE, the second electrode CE, the hole control layer HCL, and the electron control layer ECL described above with reference to FIG. 6, and thus, redundant description thereof may not be repeated.

The position in which the light receiving layer OPD is disposed in FIG. 7 may correspond to the position in which the emissive layer EML is disposed in FIG. 6. In other words, the second electrode CE′ may be disposed over the first electrode AE′, and the hole control layer HCL′, the electron control layer ECL′, and the light receiving layer OPD may be disposed between the first electrode AE′ and the second electrode CE′. The second electrode CE′ may be commonly disposed over the light receiving layers OPD of the light receiving elements LRE. The second electrode CE′ may be integrally formed with the second electrode CE illustrated in FIG. 6.

The first transistor T1′ may include a first source region S1′, a first drain region D1′, a first channel region A1′, and a first gate electrode G1′. The second transistor T2′ may include a second source region S2′, a second drain region D2′, a second channel region A2′, and a second gate electrode G2′.

A stacked structure of the first transistor T1′ may be the same or substantially the same as the stacked structure of the first transistor T1 illustrated in FIG. 6. A stacked structure of the second transistor T2′ may be the same or substantially the same as the stacked structure of the fourth transistor T4 illustrated in FIG. 6. In some embodiments, a stacked structure of the third transistor T3′ may be the same or substantially the same as the stacked structure of the first transistor T1′. Accordingly, redundant description may not be repeated.

A connecting electrode CNE′ may include a first sub-connecting electrode CNE1′ and a second sub-connecting electrode CNE2′. The first sub-connecting electrode CNE1′ may be disposed in the same layer as that of the first sub-connecting electrode CNE1 illustrated in FIG. 6, and the second sub-connecting electrode CNE2′ may be disposed in the same layer as that of the second sub-connecting electrode CNE2 illustrated in FIG. 6. Accordingly, the first sub-connecting electrode CNE1′ may be disposed on the fifth insulating layer INS5, and the second sub-connecting electrode CNE2′ may be disposed on the sixth insulating layer INS6.

The first sub-connecting electrode CNE1′ may be connected to the first gate electrode G1′ of the first transistor T1′ through a first contact hole CH1′ defined in (e.g., penetrating) the second to fifth insulating layers INS2 to INS5. The second sub-connecting electrode CNE2′ may be connected to the first sub-connecting electrode CNE1′ through a second contact hole CH2′ defined in (e.g., penetrating) the sixth insulating layer INS6. The first electrode AE′ of the light receiving element LRE may be connected to the second sub-connecting electrode CNE2′ through a third contact hole CH3′ defined in (e.g., penetrating) the seventh and eighth insulating layers INS7 and INS8.

A shielding electrode SHE may be disposed on the seventh insulating layer INS7. The shielding electrode SHE may be spaced apart from the third contact hole CH3′. The eighth insulating layer INS8 may be disposed on the seventh insulating layer INS7 to cover the shielding electrode SHE.

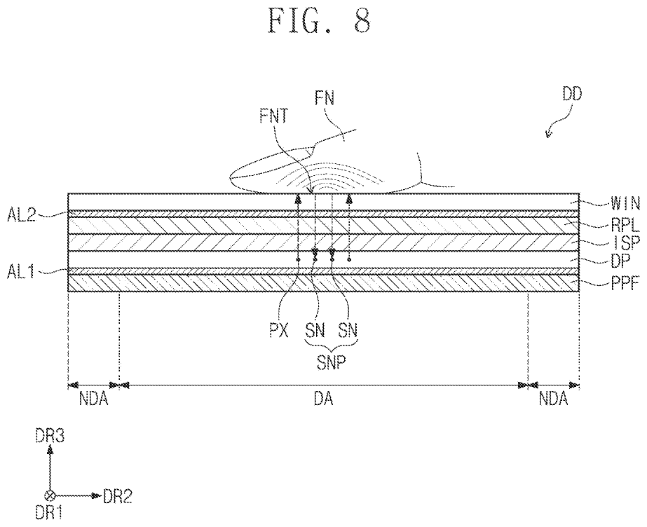

FIG. 8 is a sectional view illustrating a fingerprint sensing state by the fingerprint sensor illustrated in FIGS. 5 and 7.

Referring to FIGS. 5, 6, 7, and 8, the display device DD may include a sensing part SNP imbedded in the display panel DP, and the sensing part SNP may include a plurality of sensors SN. Each of the sensors SN may have the same configuration as that of the sensor SNij illustrated in FIGS. 5 and 7. Although two sensors SN are illustrated in FIG. 8 as an example, the present disclosure is not limited thereto, and more sensors SN may be disposed in the display panel DP to constitute the sensing part SNP.

The sensors SN may sense a fingerprint FNT of a finger FN on the display panel DP. Light generated from the light emitting elements OLED of the pixels PX may be provided to the fingerprint FNT, and may be reflected from the fingerprint FNT.

The light reflected from the fingerprint FNT may be sensed by the light receiving elements LRE of the sensors SN. The sensors SN may sense the fingerprint FNT through the light reflected from the fingerprint FNT. A control module (e.g., a controller or a control circuit) of the display device DD may receive fingerprint information sensed by the sensors SN, and may perform a user authentication mode using the received fingerprint information.

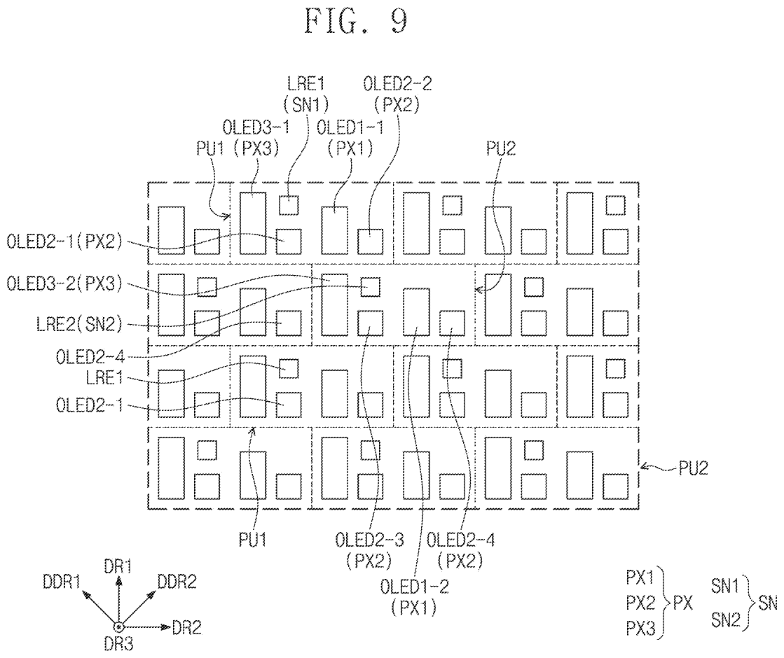

FIG. 9 is a view illustrating a planar arrangement state of the light emitting elements and the light receiving elements disposed in a partial area of the display region illustrated in FIG. 4.

Referring to FIG. 9, the display panel DP may include a plurality of first pixel units PU1 and a plurality of second pixel units PU2. The first pixel units PU1 may be arranged along the second direction DR2. The second pixel units PU2 may be arranged along the second direction DR2. The second direction DR2 may correspond to rows (e.g., a row direction).

The first pixel units PU1 may be disposed in an h-th row, and the second pixel units PU2 may be disposed in an (h+1)th row. The first pixel units PU1 disposed in the h-th row and the second pixel units PU2 disposed in the (h+1)th row may be staggered with respect to each other. For example, a first pixel unit PU1 and a second pixel unit PU2 that are adjacent to each other may be disposed along a first diagonal direction DDR1 or a second diagonal direction DDR2.

The first diagonal direction DDR1 may be defined as a direction crossing the first and second directions DR1 and DR2 on the plane defined by the first and second directions DR1 and DR2. The second diagonal direction DDR2 may be defined as a direction crossing the first diagonal direction DDR1 on the plane defined by the first and second directions DR1 and DR2.

Hereinafter, a configuration of one first pixel unit PU1 and one second pixel unit PU2 that are adjacent to each other will be described in more detail.

The first pixel unit PU1 may include a first-first light emitting element OLED1-1, a second-first light emitting element OLED2-1, a second-second light emitting element OLED2-2, a third-first light emitting element OLED3-1, and a first light receiving element LRE1. The first-first light emitting element OLED1-1, the second-first light emitting element OLED2-1, the second-second light emitting element OLED2-2, and the third-first light emitting element OLED3-1 may be arranged along the second direction DR2.

The first-first light emitting element OLED1-1, the second-first light emitting element OLED2-1, the second-second light emitting element OLED2-2, and the third-first light emitting element OLED3-1 may be arranged along the second direction DR2 in the order of the third-first light emitting element OLED3-1, the second-first light emitting element OLED2-1, the first-first light emitting element OLED1-1, and the second-second light emitting element OLED2-2.

Accordingly, the second-first light emitting element OLED2-1 may be disposed between the third-first light emitting element OLED3-1 and the first-first light emitting element OLED1-1. Furthermore, the first-first light emitting element OLED1-1 may be disposed between the second-first light emitting element OLED2-1 and the second-second light emitting element OLED2-2. The first light receiving element LRE1 may be disposed adjacent to the second-first light emitting element OLED2-1 in the first direction DR1.

The second pixel unit PU2 may include a first-second light emitting element OLED1-2, a second-third light emitting element OLED2-3, a second-fourth light emitting element OLED2-4, a third-second light emitting element OLED3-2, and a second light receiving element LRE2. The first-second light emitting element OLED1-2, the second-third light emitting element OLED2-3, the second-fourth light emitting element OLED2-4, and the third-second light emitting element OLED3-2 may be arranged along the second direction DR2.

The first-second light emitting element OLED1-2, the second-third light emitting element OLED2-3, the second-fourth light emitting element OLED2-4, and the third-second light emitting element OLED3-2 may be arranged along the second direction DR2 in the order of the third-second light emitting element OLED3-2, the second-third light emitting element OLED2-3, the first-second light emitting element OLED1-2, and the second-fourth light emitting element OLED2-4. The second light receiving element LRE2 may be disposed adjacent to the second-third light emitting element OLED2-3 in the first direction DR1.

The first-first light emitting element OLED1-1 and the first-second light emitting element OLED1-2 may display the same color as each other, for example, such as red. The second-first light emitting element OLED2-1, the second-second light emitting element OLED2-2, the second-third light emitting element OLED2-3, and the second-fourth light emitting element OLED2-4 may display the same color as each other, for example, such as green. The third-first light emitting element OLED3-1 and the third-second light emitting element OLED3-2 may display the same color as each other, for example, such as blue.

The third-first light emitting element OLED3-1 and the first-second light emitting element OLED1-2 may be arranged along the first direction DR1. The second-first light emitting element OLED2-1 and the second-fourth light emitting element OLED2-4 may be arranged along the first direction DR1. The first-first light emitting element OLED1-1 and the third-second light emitting element OLED3-2 may be arranged along the first direction DR1. The second-second light emitting element OLED2-2 and the second-third light emitting element OLED2-3 may be arranged along the first direction DR1.

The first light receiving element LRE1 may be disposed between the second-first light emitting element OLED2-1 and the second-fourth light emitting element OLED2-4. The second light receiving element LRE2 may be disposed between the second-second light emitting element OLED2-2 and the second-third light emitting element OLED2-3.

Each of the first-first and first-second light emitting elements OLED1-1 and OLED1-2, the second-first to second-fourth light emitting elements OLED2-1 to OLED2-4, and the third-first and third-second light emitting elements OLED3-1 and OLED3-2 may have the same or substantially the same configuration as that of the light emitting element OLED illustrated in FIGS. 5 and 6. Each of the first and second light receiving elements LRE1 and LRE2 may have the same or substantially the same configuration as that of the light receiving element LRE illustrated in FIGS. 5 and 7.

The pixel circuit PC illustrated in FIG. 5 may be provided in plural numbers, and the plurality of pixel circuits PC may drive the first-first and first-second light emitting elements OLED1-1 and OLED1-2, the second-first to second-fourth light emitting elements OLED2-1 to OLED2-4, and the third-first and third-second light emitting elements OLED3-1 and OLED3-2, respectively.

The pixel circuits PC may be disposed below (e.g., underneath) the first-first and first-second light emitting elements OLED1-1 and OLED1-2, the second-first to second-fourth light emitting elements OLED2-1 to OLED2-4, and the third-first and third-second light emitting elements OLED3-1 and OLED3-2.

The pixel circuits PC may be connected to the first-first and first-second light emitting elements OLED1-1 and OLED1-2, the second-first to second-fourth light emitting elements OLED2-1 to OLED2-4, and the third-first and third-second light emitting elements OLED3-1 and OLED3-2, respectively.

The sensing circuit SNC illustrated in FIG. 5 may be provided in plural numbers, and the plurality of sensing circuits SNC may drive the first and second light receiving elements LRE1 and LRE2, respectively. The sensing circuits SNC may be disposed below (e.g., underneath) the first and second light receiving elements LRE1 and LRE2, and may be connected to the first and second light receiving elements LRE1 and LRE2, respectively.

The pixels PX illustrated in FIG. 4 may include a plurality of first pixels PX1, a plurality of second pixels PX2, and a plurality of third pixels PX3. The sensors SN illustrated in FIG. 8 may include a plurality of first sensors SN1 and a plurality of second sensors SN2.

Each of the first pixel unit PU1 and the second pixel unit PU2 may include a first pixel PX1, second pixels PX2, and a third pixel PX3. In the first and second pixel units PU1 and PU2, the first pixels PX1 may be defined as a pixel PX including the first-first light emitting element OLED1-1 and a pixel PX including the first-second light emitting element OLED1-2.

In the first and second pixel units PU1 and PU2, the second pixels PX2 may be defined as a pixel PX including the second-first light emitting element OLED2-1, a pixel PX including the second-second light emitting element OLED2-2, a pixel PX including the second-third light emitting element OLED2-3, and a pixel PX including the second-fourth light emitting element OLED2-4.

In the first and second pixel units PU1 and PU2, the third pixels PX3 may be defined as a pixel PX including the third-first light emitting element OLED3-1 and a pixel PX including the third-second light emitting element OLED3-2.

In the first and second pixel units PU1 and PU2, the first sensor SN1 may be defined as a sensor SN including the first light receiving element LRE1, and the second sensor SN2 may be defined as a sensor SN including the second light receiving element LRE2. The first sensor SN1 and the second sensor SN2 may be disposed along the first diagonal direction DDR1 or the second diagonal direction DDR2.

Each of the first, second, and third pixels PX1, PX2, and PX3 may include a corresponding pixel circuit PC from among the above-described pixel circuits PC. Each of the first and second sensors SN1 and SN2 may include a corresponding sensing circuit SNC from among the above-described sensing circuits SNC. The sensing circuit SNC of each of the first sensors SN1 may be defined as a first sensing circuit. The sensing circuit SNC of each of the second sensors SN2 may be defined as a second sensing circuit.

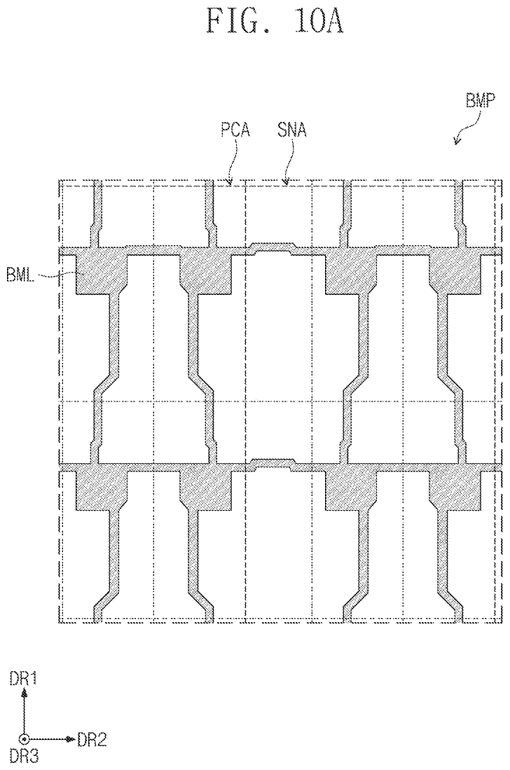

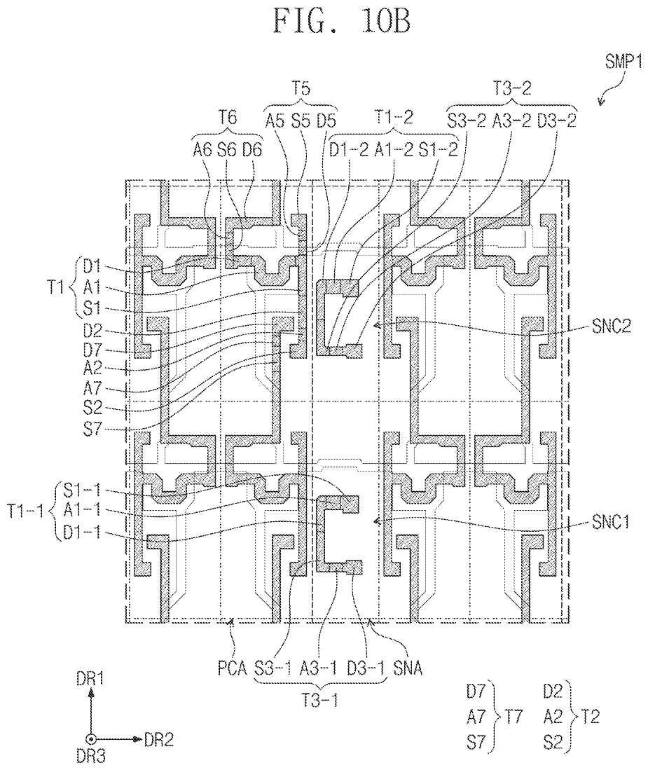

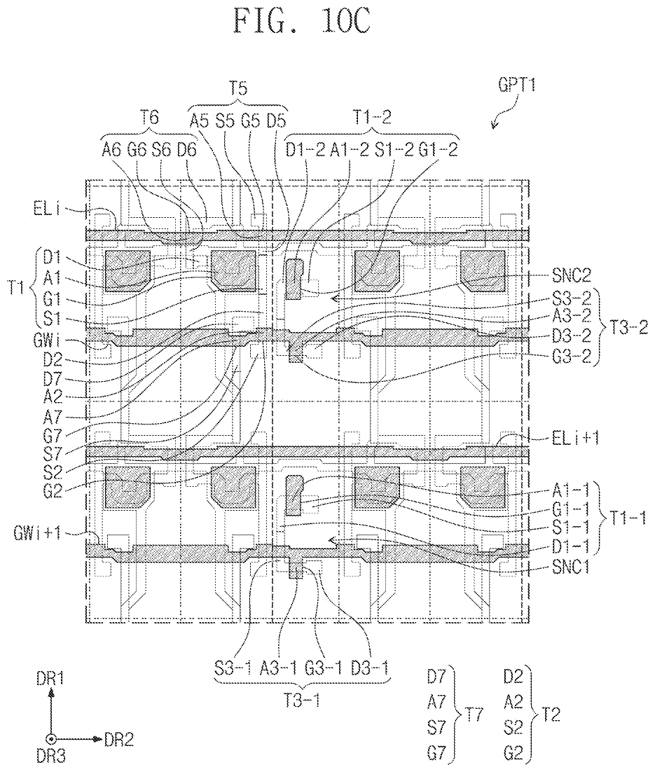

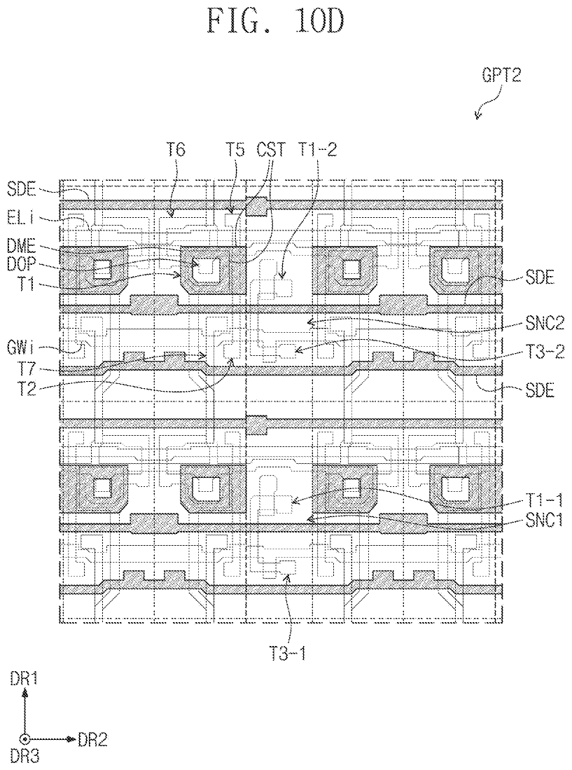

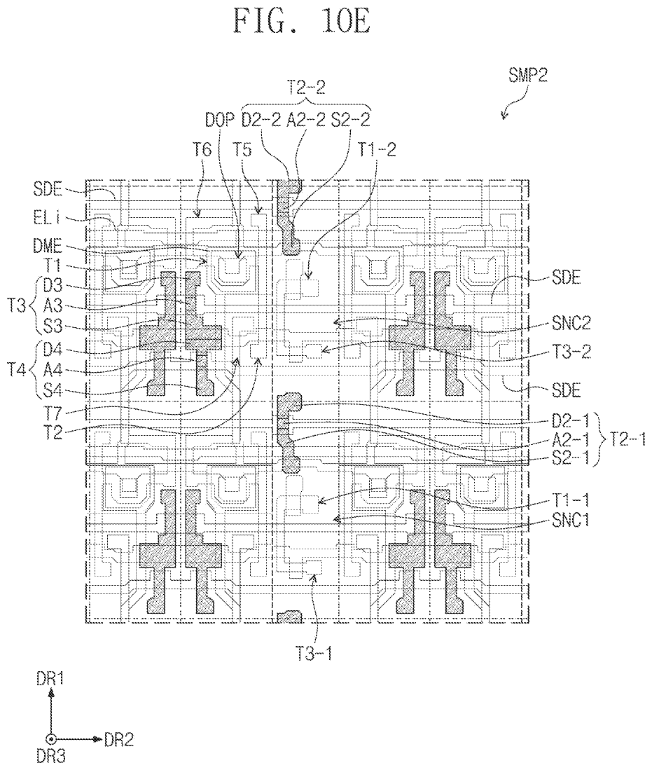

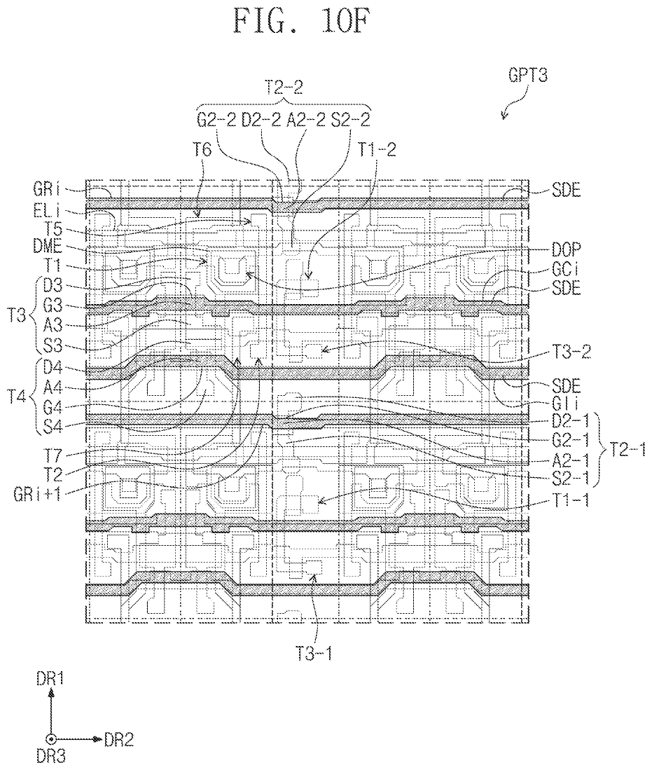

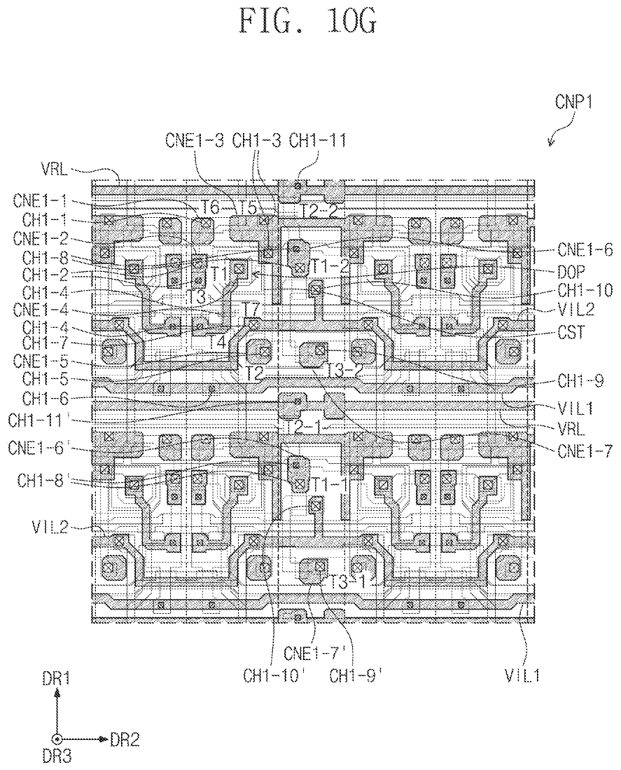

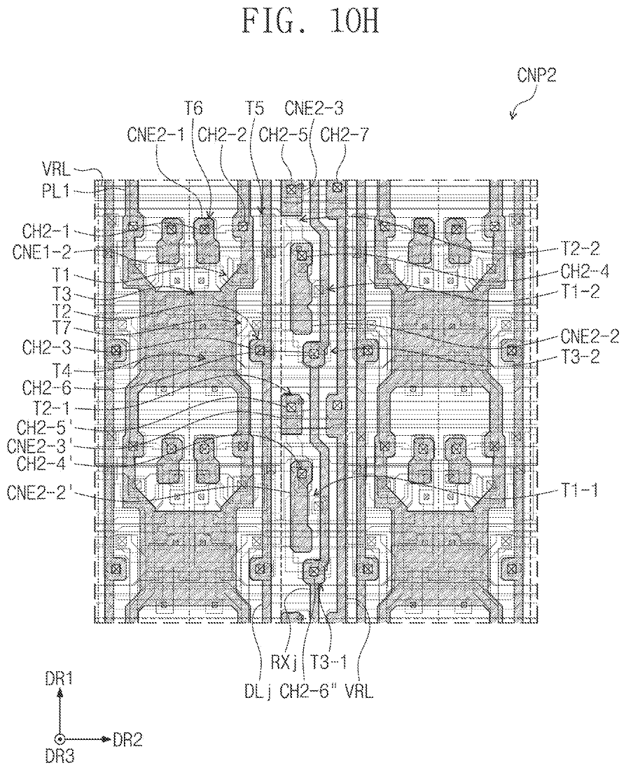

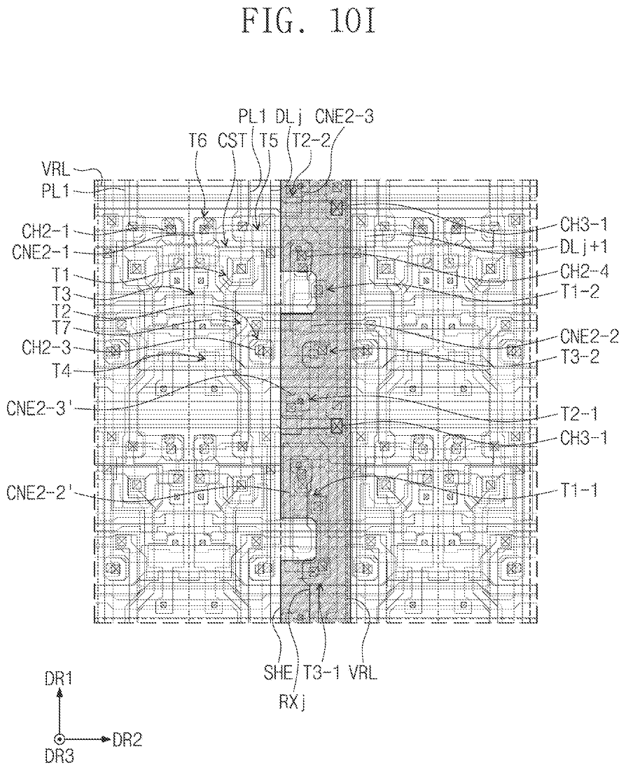

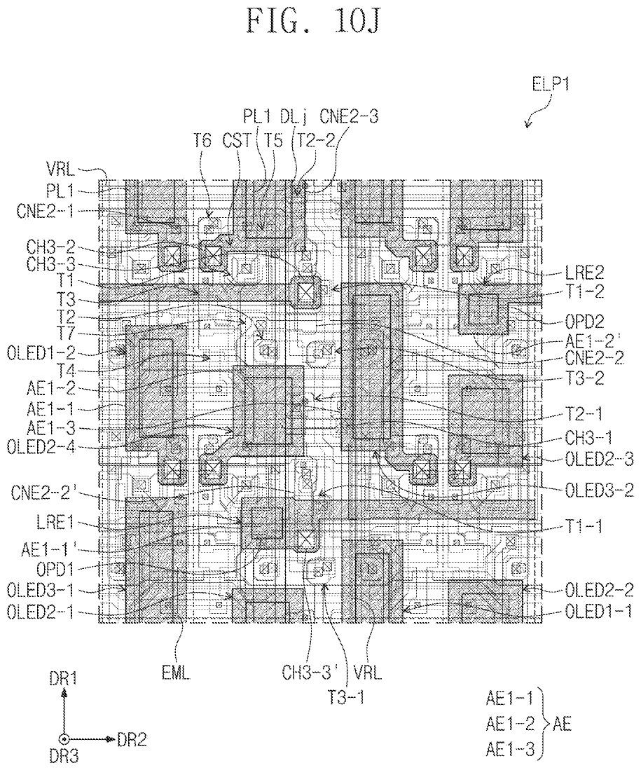

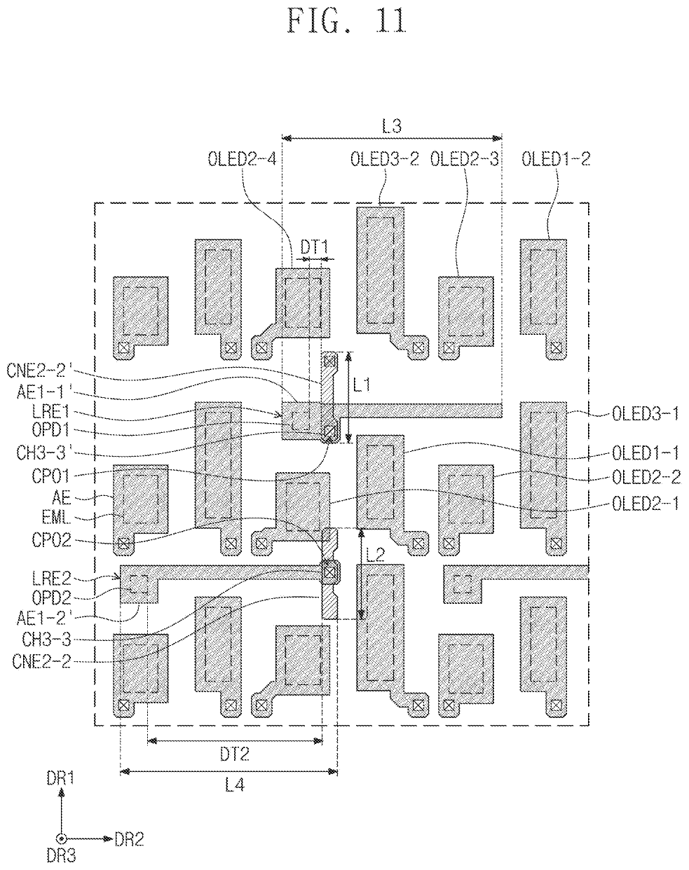

FIGS. 10A through 10J are views illustrating planar structures of some of the pixels and some of the sensors illustrated in FIG. 9 in stages.

FIGS. 10A through 10J may be defined as layout drawings of the pixel PX and the sensor SN. Hereinafter, configurations of one pixel PX, one first sensor SN1, and one second sensor SN2 will be described in more detail with reference to FIGS. 10A through 10J.

Regions partitioned by dotted lines illustrated in FIGS. 10A to 10J may be defined as pixel circuit regions PCA and sensing circuit regions SNA. The above-described pixel circuits PC may be disposed in the pixel circuit regions PCA, and the above-described sensing circuits SNC may be disposed in the sensing circuit regions SNA. The reference numerals of the pixel circuit regions PCA and the sensing circuit regions SNA are illustrated in FIGS. 10A and 10B, and omitted in the other drawings.

Referring to FIG. 10A, a lower conductive pattern BMP may be disposed on the substrate SUB illustrated in FIGS. 6 and 7. The lower metal layer BML may be formed by the lower conductive pattern BMP. The lower conductive pattern BMP may have various suitable shapes without being limited to the shape illustrated in FIG. 10A.

Referring to FIGS. 10A and 10B, a first semiconductor pattern SMP1 may be disposed on the lower conductive pattern BMP. The first, second, fifth, sixth, and seventh source regions S1, S2, S5, S6, and S7, the first, second, fifth, sixth, and seventh drain regions D1, D2, D5, D6, and D7, and the first, second, fifth, sixth, and seventh channel regions A1, A2, A5, A6, and A7 of the first, second, fifth, sixth, and seventh transistors T1, T2, T5, T6, and T7 may be formed by the first semiconductor pattern SMP1.

The first, second, fifth, sixth, and seventh channel regions A1, A2, A5, A6, and A7 may be disposed between the first, second, fifth, sixth, and seventh source regions S1, S2, S5, S6, and S7 and the first, second, fifth, sixth, and seventh drain regions D1, D2, D5, D6, and D7, respectively.

The second drain region D2 of the second transistor T2 and the fifth drain region D5 of the fifth transistor T5 may extend from the first source region S1 of the first transistor T1. The sixth source region S6 of the sixth transistor T6 may extend from the first drain region D1 of the first transistor T1. The seventh source region S7 of the seventh transistor T7 may extend from the sixth drain region D6 of the sixth transistor T6.

As such, the first transistor T1 may be connected to the second, fifth, and sixth transistors T2, T5, and T6, and the sixth transistor T6 may be connected to the seventh transistor T7.

In FIG. 10B, the seventh transistor T7 indicated by the reference numeral T7 may be the seventh transistor T7 of the next-stage pixel PX. Because, in FIG. 5, the seventh transistor T7 receives the (i−1)th write scan signal GWSi−1 that is the write scan signal of the previous stage, the seventh transistor T7 of the next-stage pixel PX may be disposed in the pixel circuit region PCA of a previous-stage pixel PX.

As described above with reference to FIG. 9, the first sensor SN1 may include the first sensing circuit SNC1, and the second sensor SN2 may include the second sensing circuit SNC2. The first sensing circuit SNC1 and the second sensing circuit SNC2 may be spaced apart from each other in the first direction DR1.

First-first and third-first source regions S1-1 and S3-1, first-first and third-first drain regions D1-1 and D3-1, and first-first and third-first channel regions A1-1 and A3-1 of first-first and third-first transistors T1-1 and T3-1 of the first sensing circuit SNC1 may be formed by the first semiconductor pattern SMP1.

The first-first and third-first channel regions A1-1 and A3-1 may be disposed between the first-first and third-first source regions S1-1 and S3-1 and the first-first and third-first drain regions D1-1 and D3-1, respectively. The third-first source region S3-1 of the third-first transistor T3-1 may extend from the first-first drain region D1-1 of the first-first transistor T1-1. As such, the first-first transistor T1-1 may be connected to the third-first transistor T3-1.

First-second and third-second source regions S1-2 and S3-2, first-second and third-second drain regions D1-2 and D3-2, and first-second and third-second channel regions A1-2 and A3-2 of the first-second and third-second transistors T1-2 and T3-2 of the second sensing circuit SNC2 may be formed by the first semiconductor pattern SMP1.

The first-second and third-second channel regions A1-2 and A3-2 may be disposed between the first-second and third-second source regions S1-2 and S3-2 and the first-second and third-second drain regions D1-2 and D3-2, respectively. The third-second source region S3-2 of the third-second transistor T3-2 may extend from the first-second drain region D1-2 of the first-second transistor T1-2. As such, the first-second transistor T1-2 may be connected to the third-second transistor T3-2.

Referring to FIGS. 10A through 10C, a first gate pattern GPT1 may be disposed on the first semiconductor pattern SMP1. The first gate pattern GPT1 may include the i-th write scan line GWi (hereinafter, referred to as the write scan line), the i-th light emission line ELi (hereinafter, referred to as the light emission line), and the first gate electrode G1.

The write scan line GWi and the light emission line ELi may extend in the second direction DR2, and may be spaced apart from each other in the first direction DR1. The first gate electrode G1 may be disposed between the write scan line GWi and the light emission line ELi.

The first gate electrode G1 of the first transistor T1 may be formed by the first gate pattern GPT1. The first gate electrode G1 may overlap with the first channel region A1.

The light emission line ELi may extend to cross the first semiconductor pattern SMP1. The fifth gate electrode G5 of the fifth transistor T5 and the sixth gate electrode G6 of the sixth transistor T6 may be formed by the light emission line ELi.

Portions of the light emission line ELi that overlap with the first semiconductor pattern SMP1 when viewed from above the plane (e.g., in a plan view) may be defined as the fifth and sixth gate electrodes G5 and G6. When viewed from above the plane (e.g., in a plan view), the fifth gate electrode G5 may overlap with the fifth channel region A5, and the sixth gate electrode G6 may overlap with the sixth channel region A6.

The write scan line GWi may extend to cross the first semiconductor pattern SMP1. The second gate electrode G2 of the second transistor T2 and the seventh gate electrode G7 of the seventh transistor T7 may be formed by the write scan line GWi.

Portions of the write scan line GWi that overlap with the first semiconductor pattern SMP1 when viewed from above the plane (e.g., in a plan view) may be defined as the second and seventh gate electrodes G2 and G7. When viewed from above the plane (e.g., in a plan view), the second gate electrode G2 may overlap with the second channel region A2, and the seventh gate electrode G7 may overlap with the seventh channel region A7.

The first gate pattern GPT1 may include a first-first gate electrode G1-1, a first-second gate electrode G1-2, the (i+1)th write scan line GWi+1, and the (i+1)th light emission line ELi+1.

The first-second gate electrode G1-2 may be disposed between the write scan line GWi and the light emission line ELi. The first-first gate electrode G1-1 may be disposed between the (i+1)th write scan line GWi+1 and the (i+1)th light emission line ELi+1.

The first-first gate electrode G1-1 of the first-first transistor T1-1 and the first-second gate electrode G1-2 of the first-second transistor T1-2 may be formed by the first gate pattern GPT1. The first-first gate electrode G1-1 may overlap with the first-first channel region A1-1, and the first-second gate electrode G1-2 may overlap with the first-second channel region A1-2.

The first and sixth transistors T1 and T6 may correspond to the first and sixth transistors T1 and T6 illustrated in FIGS. 5 and 6. Each of the first-first and first-second transistors T1-1 and T1-2 may correspond to the first transistor T1′ of the sensor SNij illustrated in FIGS. 5 and 7. Each of the third-first and third-second transistors T3-1 and T3-2 may correspond to the third transistor T3′ illustrated in FIG. 5.

In FIGS. 10D through 10J, for convenience of illustration, the reference numerals of the source regions, the drain regions, the channel regions, and the gate electrodes of the first, second, fifth, sixth, and seventh transistors T1, T2, T5, T6, and T7 and the reference numerals of the source regions, the drain regions, the channel regions, and the gate electrodes of the first-first, first-second, third-first, and third-second transistors T1-1, T1-2, T3-1, and T3-2 are omitted, and the reference numerals for the first, second, fifth, sixth, and seventh transistors T1, T2, T5, T6, and T7 and the first-first, first-second, third-first, and third-second transistors T1-1, T1-2, T3-1, and T3-2 are illustrated generally.

Referring to FIGS. 10A to 10D, a second gate pattern GPT2 may be disposed on the first gate pattern GPT1. The second gate pattern GTP2 may include the dummy electrode DME and sub-dummy electrodes SDE.

The dummy electrode DME may overlap with the first gate electrode G1 when viewed from above the plane (e.g., in a plan view). The dummy electrode DME may form the capacitor CST together with the first gate electrode G1. An opening DOP may be defined in the dummy electrode DME.

The sub-dummy electrodes SDE may extend in the second direction DR2, and may be arranged along the first direction DR1. When viewed from above the plane (e.g., in a plan view), the sub-dummy electrodes SDE may overlap with the reset line GRi, the compensation scan line GCi, and the initialization scan line Gli illustrated in FIG. 10F.

Referring to FIGS. 10A to 10E, a second semiconductor pattern SMP2 may be disposed on the second gate pattern GPT2. The third and fourth source regions S3 and S4, the third and fourth drain regions D3 and D4, and the third and fourth channel regions A3 and A4 of the third and fourth transistors T3 and T4 may be formed by the second semiconductor pattern SMP2.

The third and fourth channel regions A3 and A4 may be disposed between the third and fourth source regions S3 and S4 and the third and fourth drain regions D3 and D4, respectively. The fourth drain region D4 of the fourth transistor T4 may extend from the third source region S3 of the third transistor T3. As such, the fourth transistor T4 may be connected to the third transistor T3.

A second-first source region S2-1, a second-first drain region D2-1, and a second-first channel region A2-1 of a second-first transistor T2-1 of the first sensing circuit SNC1 may be formed by the second semiconductor pattern SMP2. A second-second source region S2-2, a second-second drain region D2-2, and a second-second channel region A2-2 of a second-second transistor T2-2 of the second sensing circuit SNC2 may be formed by the second semiconductor pattern SMP2.

The second-first channel region A2-1 may be disposed between the second-first source region S2-1 and the second-first drain region D2-1. The second-second channel region A2-2 may be disposed between the second-second source region S2-2 and the second-second drain region D2-2.

Referring to FIGS. 10A to 10F, a third gate pattern GPT3 may be disposed on the second semiconductor pattern SMP2. The third gate pattern GPT3 may include the reset line GRi, the compensation scan line GCi, and the initialization scan line Gli.

The reset line GRi, the compensation scan line GCi, and the initialization scan line Gli may extend in the second direction DR2, and may be arranged along the first direction DR1. The reset line GRi, the compensation scan line GCi, and the initialization scan line Gli may be disposed to overlap with the sub-dummy electrodes SDE, respectively.

The light emission line ELi may be disposed between the reset line GRi and the dummy electrode DME. The compensation scan line GCi may be disposed between the dummy electrode DME and the write scan line GWi. The write scan line GWi may be disposed between the compensation scan line GCi and the initialization scan line Gli.

The compensation scan line GCi may extend to cross the second semiconductor pattern SMP2. The third gate electrode G3 of the third transistor T3 may be formed by the compensation scan line GCi. A portion of the compensation scan line GCi that overlaps with the second semiconductor pattern SMP2 when viewed from above the plane (e.g., in a plan view) may be defined as the third gate electrode G3.

The initialization scan line Gli may extend to cross the second semiconductor pattern SMP2. The fourth gate electrode G4 of the fourth transistor T4 may be formed by the initialization scan line Gli. A portion of the initialization scan line Gli that overlaps with the second semiconductor pattern SMP2 when viewed from above the plane (e.g., in a plan view) may be defined as the fourth gate electrode G4.

The reset line GRi may extend to cross the second semiconductor pattern SMP2. A second-second gate electrode G2-2 of the second-second transistor T2-2 may be formed by the reset line GRi. A portion of the reset line GRi that overlaps with the second semiconductor pattern SMP2 when viewed from above the plane (e.g., in a plan view) may be defined as the second-second gate electrode G2-2.

The third gate pattern GPT3 may include the (i+1)th reset line GRi+1. The (i+1)th reset line GRi+1 may extend to cross the second semiconductor pattern SMP2. A second-first gate electrode G2-1 of the second-first the transistor T2-1 may be formed by the (i+1)th reset line GRi+1. A portion of the (i+1)th reset line GRi+1 that overlaps with the second semiconductor pattern SMP2 when viewed from above the plane (e.g., in a plan view) may be defined as the second-first gate electrode G2-1.

The fourth transistor T4 may correspond to the fourth transistor T4 illustrated in FIGS. 5 and 6. The second-first the transistor T2-1 and the second-second transistor T2-2 may correspond to the second transistor T2′ of the sensor SNij illustrated in FIGS. 5 and 7.

In FIGS. 10G through 10J, for convenience of illustration, the reference numerals of the source regions, the drain regions, the channel regions, and the gate electrodes of the third and fourth transistors T3 and T4 and the reference numerals of the source regions, the drain regions, the channel regions, and the gate electrodes of the second-first and second-second transistors T2-1 and T2-2 are omitted, and the reference numerals for the third and fourth transistors T3 and T4 and the second-first and second-second transistors T2-1 and T2-2 are illustrated generally.

Referring to FIGS. 10A to 10G, a first connecting pattern CNP1 may be disposed on the third gate pattern GPT3. The first connecting pattern CNP1 may include first-first to first-seventh connecting electrodes CNE1-1 to CNE1-7 and CNE1-7′, the first initialization line VIL1, the second initialization line VIL2, and the reset voltage line VRL. The first-first to first-seventh connecting electrodes CNE1-1 to CNE1-7 and CNE1-7′ may correspond to the first sub-connecting electrodes CNE1 and CNE1′ illustrated in FIGS. 6 and 7.

The first initialization line VIL1, the second initialization line VIL2, and the reset voltage line VRL may extend in the second direction DR2, and may be arranged along the first direction DR1. The first initialization line VIL1 may be adjacent to the fourth transistor T4, and the second initialization line VIL2 may be disposed to be adjacent to the seventh transistor T7. The reset voltage line VRL may be adjacent to the reset line GRi.

The first-first connecting electrode CNE1-1 may be connected to the sixth transistor T6 through a first-first contact hole CH1-1. The first-first connecting electrode CNE1-1 may be connected to the sixth drain region D6 of the sixth transistor T6. The first-first connecting electrode CNE1-1 may be the first sub-connecting electrode CNE1 illustrated in FIG. 6, and the first-first contact hole CH1-1 may be the first contact hole CH1 illustrated in FIG. 6.

The first-second connecting electrode CNE1-2 may be connected to the third transistor T3 and the first and sixth transistors T1 and T6 through contact holes 1-2 CH1-2. The first-second connecting electrode CNE1-2 may be connected to the first drain region D1 of the first transistor T1, the sixth source region S6 of the sixth transistor T6, and the third drain region D3 of the third transistor T3. The third transistor T3 may be connected to the first and sixth transistors T1 and T6 by the first-third connecting electrode CNE1-3.

The first-third connecting electrode CNE1-3 may be connected to the fifth transistor T5 and the dummy electrode DME of the capacitor CST through first-third contact holes CH1-3. The first-third connecting electrode CNE1-3 may be connected to the fifth source region S5 of the fifth transistor T5.

The first-fourth connecting electrode CNE1-4 may be connected to the third and fourth transistors T3 and T4 and the first gate electrode G1 of the first transistor T1 through a first-fourth contact hole CH1-4. The first-fourth connecting electrode CNE1-4 may be connected to the third source region S3 of the third transistor T3. The third and fourth transistors T3 and T4 may be electrically connected to the first transistor T1 by the first-fourth connecting electrode CNE1-4.

A portion of the first gate electrode G1 may be exposed by the opening DOP formed in the dummy electrode DME. The first-fourth contact hole CH1-4 may be formed to overlap with the opening DOP, and the first-fourth connecting electrode CNE1-4 may be easily connected to the first gate electrode G1 accordingly.

The first-fifth connecting electrode CNE1-5 may be connected to the second transistor T2 through a first-fifth contact hole CH1-5. The first-fifth connecting electrode CNE1-5 may be connected to the second source region S2 of the second transistor T2.

The first initialization line VIL1 may be connected to the fourth transistor T4 through a first-sixth contact hole CH1-6. The first initialization line VIL1 may be connected to the fourth source region S4 of the fourth transistor T4.

The second initialization line VIL2 may be connected to the seventh transistor T7 through a first-seventh contact hole 1-7 CH1-7. The second initialization line VIL2 may be connected to the seventh drain region D7 of the seventh transistor T7.

The first-sixth connecting electrode CNE1-6 may be connected to the first-second transistor T1-2 and the second-second transistor T2-2 through first-eighth contact holes CH1-8. The first-sixth connecting electrode CNE1-6 may be connected to the first-second gate electrode G1-2 of the first-second transistor T1-2 and the second-second source region S2-2 of the second-second transistor T2-2.

The first-seventh connecting electrode CNE1-7 may be connected to the third-second transistor T3-2 through a first-ninth contact hole CH1-9. The first-seventh connecting electrode CNE1-7 may be connected to the third-second drain region D3-2 of the third third-second transistor T3-2.

The second initialization line VIL2 may be connected to the first-second transistor T1-2 through a first-tenth contact hole CH1-10. The second initialization line VIL2 may be connected to the first-second source region S1-2 of the first-second transistor T1-2.

The reset voltage line VRL may be connected to the second-second transistor T2-2 through a first-eleventh contact hole CH1-11. The reset voltage line VRL may be connected to the second-second drain region D2-2 of the second-second transistor T2-2.

A first-sixth connecting electrode CNE1-6′ may be connected to the first-first transistor T1-1 and the second-first the transistor T2-1 through first-eight contact holes CH1-8′. The first-sixth connecting electrode CNE1-6′ may be connected to the first-first gate electrode G1-1 of the first-first transistor T1-1 and the second-first source region S2-1 of the second-first transistor T2-1.

The first-seventh connecting electrode CNE1-7′ may be connected to the third-first transistor T3-1 through a first-ninth contact hole CH1-9′. The first-seventh connecting electrode CNE1-7′ may be connected to the third-first drain region D3-1 of the third-first transistor T3-1.

The second initialization line VIL2 may be connected to the first-first transistor T1-1 through a first-tenth contact hole CH1-10′. The second initialization line VIL2 may be connected to the first-first source region S1-1 of the first-first transistor T1-1.

The reset voltage line VRL may be connected to the second-first transistor T2-1 through a first-eleventh contact hole CH1-11′. The reset voltage line VRL may be connected to the second-first drain region D2-1 of the second-first transistor 2-1 T2-1.

A plurality of first initialization lines VIL1, a plurality of second initialization lines VIL2, and a plurality of reset voltage lines VRL are illustrated. However, substantially, the first initialization lines VIL1 may be commonly connected at the outer periphery of the display region DA. In addition, the second initialization lines VIL2 may also be commonly connected at the outer periphery of the display region DA, and the reset voltage lines VRL may also be commonly connected at the outer periphery of the display region DA.

Referring to FIGS. 10A to 10H, a second connecting pattern CNP2 may be disposed on the first connecting pattern CNP1. The second connecting pattern CNP2 may include the first power line PL1, the data line DLj, the receive line RXj, second-first to second-third connecting electrodes CNE2-1 to CNE2-3 and CNE2-3′, and the reset voltage line VRL extending in the first direction DR1.

The first power line PL1, the data line DLj, the receive line RXj, and the reset voltage line VRL may extend in the first direction DR2, and may be arranged along the second direction DR2. The second-first to second-third connecting electrodes CNE2-1 to CNE2-3 and CNE2-3′ may correspond to the second sub-connecting electrodes CNE2 and CNE2′ illustrated in FIGS. 6 and 7.

The reference numerals of the first-first to first-seventh connecting electrodes CNE1-1 to CNE1-7 and CNE1-7′ and the first-first to first-eleventh contact holes CH1-1 to CH1-11 and CH1-11′ illustrated in FIG. 10G are omitted in FIG. 10H.

The second-first connecting electrode CNE2-1 may be connected to the first-first connecting electrode CNE1-1 through a second-first contact hole CH2-1. Accordingly, the second-first connecting electrode CNE2-1 may be connected to the sixth transistor T6 through the first-first connecting electrode CNE1-1. The second-first connecting electrode CNE2-1 may be the second sub-connecting electrode CNE2 illustrated in FIG. 6, and the second-first contact hole CH2-1 may be the second contact hole CH2 illustrated in FIG. 6.

The first power line PL1 may be connected to the first-third connecting electrode CNE1-3 through a second-second contact hole CH2-2. Accordingly, the first power line PL1 may be connected to the fifth transistor T5 and the capacitor CST through the first-third connecting electrode CNE1-3.

The data line DLj may be connected to the first-fifth connecting electrode CNE1-5 through a second-third contact hole CH2-3. Accordingly, the data line DLj may be connected to the second transistor T2 through the first-fifth connecting electrode CNE1-5.

The second-second connecting electrode CNE2-2 may be connected to the first-sixth connecting electrode CNE1-6 through a second-fourth contact hole CH2-4. Accordingly, the second-second connecting electrode CNE2-2 may be connected to the first-second transistor T1-2 and the second-second transistor T2-2 through the first-sixth connecting electrode CNE1-6. The second-second connecting electrode CNE2-2 may be the second sub-connecting electrode CNE2′ illustrated in FIG. 7, and the second-fourth contact hole CH2-4 may be the second contact hole CH2′ illustrated in FIG. 7.

The second-third connecting electrode CNE2-3 may be connected, through a second-fifth contact hole CH2-5, to the reset voltage line VRL extending in the second direction DR2 illustrated in FIG. 10G. The second-third connecting electrode CNE2-3 may overlap with a protruding portion of the reset line GRi illustrated in FIG. 10D.

The receive line RXj may be connected to the first-seventh connecting electrode CNE1-7 through a second-sixth contact hole CH2-6. Accordingly, the receive line RXj may be connected to the third-second transistor T3-2 through the first-seventh connecting electrode CNE1-7.

The reset voltage line VRL extending in the first direction DR1 may be connected, through a second-seventh contact hole CH2-7, to the reset voltage line VRL extending in the second direction DR2 illustrated in FIG. 10G.

A second-second connecting electrode CNE2-2′ may be connected to the first-sixth connecting electrode CNE1-6′ through a second-fourth contact hole CH2-4′. Accordingly, the second-second connecting electrode CNE2-2′ may be connected to the first-first transistor T1-1 and the second-first the transistor T2-1 through the first-sixth connecting electrode CNE1-6′.

The second-third connecting electrode CNE2-3′ may be connected, through a second-fifth contact hole CH2-5′, to the reset voltage line VRL extending in the second direction DR2 illustrated in FIG. 10G.

The receive line RXj may be connected to the first-seventh connecting electrode CNE1-7′ through a second-sixth contact hole CH2-6′. Accordingly, the receive line RXj may be connected to the third-first transistor T3-1 through the first-seventh connecting electrode CNE1-7′.

Hereinafter, the second-second connecting electrode CNE2-2′ is defined as the first connecting electrode CNE2-2′, and the second-second connecting electrode CNE2-2 is defined as the second connecting electrode CNE2-2.

Referring to FIGS. 10A to 10I, the shielding electrode SHE may be disposed on the second connecting pattern CNP2. The shielding electrode SHE may extend in the first direction DR1. The shielding electrode SHE may be the shielding electrode SHE illustrated in FIG. 7.

The shielding electrode SHE may be connected, through third-first contact holes CH3-1, to the reset voltage line VRL extending in the first direction DR1 illustrated in FIG. 10H. Accordingly, the shielding electrode SHE may receive a constant voltage. The shielding electrode SHE may not overlap with third-third contact holes CH3-3 and CH3-3′. The third-first contact holes CH3-1 may be defined in (e.g., may penetrate) the seventh insulating layer INS7 illustrated in FIG. 7.

Data voltages applied to the data lines DLj and DLj+1 may be pulsed signals. The pulsed signals may affect the sensing signal RS output through the receive line RXj. When viewed from above the plane (e.g., in a plan view), the shielding electrode SHE may be disposed between the data lines DLj and DLj+1, and may block an influence of the pulsed data voltages on the sensing signal RS.

Referring to FIGS. 10A to 10J, a first electrode pattern ELP1 may be disposed on the shielding electrode SHE. The first electrode pattern ELP1 may include a plurality of first electrodes AE and a plurality of first electrodes AE1′. Each of the first electrodes AE may be the first electrode AE illustrated in FIG. 6. Each of the first electrodes AE1′ may be the first electrode AE′ illustrated in FIG. 7.

The first electrodes AE may include first-first electrodes AE1-1, first-second electrodes AE1-2, and first-third electrodes AE1-3. The first-first electrodes AE1-1 may be the first electrodes of the first-first and first-second light emitting elements OLED1-1 and OLED1-2 illustrated in FIG. 9.

The first-second electrodes AE1-2 may be the first electrodes of the second-first, second-second, second-third, and second-fourth light emitting elements OLED2-1, OLED2-2, OLED2-3, and OLED2-4 illustrated in FIG. 9. The first-third electrodes AE1-3 may be the first electrodes of the third-first and third-second light emitting elements OLED3-1 and OLED3-2 illustrated in FIG. 9.

The first electrodes AE′ may include a first-first electrode AE1-1′ and an first-second electrode AE1-2′. The first-first electrode AE1-1′ may be the first electrode of each of the first light receiving elements LRE1 illustrated in FIG. 9. The first-second electrode AE1-2′ may be the first electrode of each of the second light receiving elements LRE2 illustrated in FIG. 9.

A quadrangular region (e.g., illustrated as a dotted rectangle) defined inside each of the first electrodes AE may be the emissive layer EML disposed in the opening PX_OP illustrated in FIG. 6. A quadrangular region (e.g., illustrated as a dotted rectangle) defined inside each of the first electrodes AE′ may be the light receiving layer OPD disposed in the opening PX_OP′ illustrated in FIG. 7. Hereinafter, the light receiving layer OPD of the first light receiving element LRE1 is defined as the first light receiving layer OPD1, and the light receiving layer OPD of the second light receiving element LRE2 is defined as the second light receiving layer OPD2.

Hereinafter, any one first electrode AE connected to the second-first connecting electrode CNE2-1 will be described in more detail. The first electrode AE may be connected to the second-first connecting electrode CNE2-1 illustrated in FIG. 10I through a third-second contact hole CH3-2. Accordingly, the first electrode AE may be connected to the sixth transistor T6 through the second-first connecting electrode CNE2-1 and the first-first connecting electrode CNE1-1. The third-second contact holes CH3-2 may correspond to the third contact hole CH3 illustrated in FIG. 6.

The first-first electrode AE1-1′ may be connected to the first connecting electrode CNE2-2′ through the third-third contact hole CH3-3′. Accordingly, the first-first electrode AE1-1′ may be connected to the first-first transistor T1-1 through the first connecting electrode CNE2-2′ and the first-sixth connecting electrode CNE1-6′. In other words, the first light receiving element LRE1 may be connected to the first-first transistor T1-1 through the first connecting electrode CNE2-2′ and the first-sixth connecting electrode CNE1-6′.

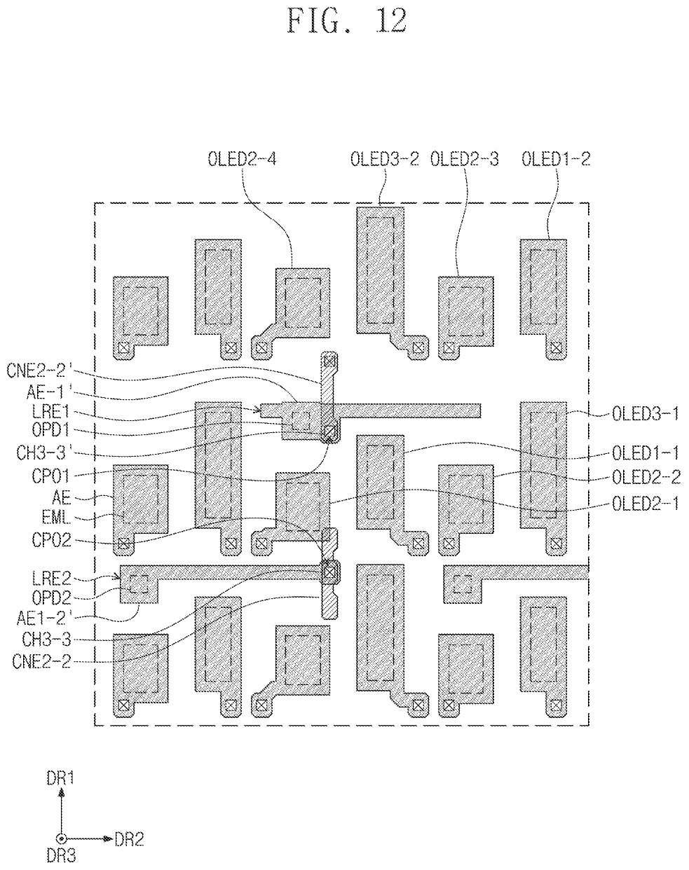

The first-second electrode AE1-2′ may be connected to the second connecting electrode CNE2-2 through the third-third contact hole CH3-3. The third-third contact hole CH3-3′ and the third-third contact hole CH3-3 may correspond to the third contact hole CH3′ illustrated in FIG. 7. Depending on the area of the illustrated layout, portions of the first-second electrode AE1-2′ are cut off. The first-second electrode AE1-2′ will be described in more detail below with reference to FIG. 11.

The first-second electrode AE1-2′ may be connected to the first-second transistor T1-2 through the second connecting electrode CNE2-2 and the first-sixth connecting electrode CNE1-6. In other words, the second light receiving element LRE2 may be connected to the first-second transistor T1-2 through the second connecting electrode CNE2-2 and the first-sixth connecting electrode CNE1-6.

The first-first electrode AE1-1′ may be connected to the first-first gate electrode G1-1 of the first-first transistor T1-1 through the first connecting electrode CNE2-2′ and the first-sixth connecting electrode CNE1-6′. The first-second electrode AE1-2′ may be connected to the first-second gate electrode G1-2 of the first-second transistor T1-2 through the second connecting electrode CNE2-2 and the first-sixth connecting electrode CNE1-6.

The first light receiving layer OPD1 may be adjacent to the first-first transistor T1-1. However, the second light receiving layer OPD2 may be spaced apart from the first-second transistor T1-2. For example, when viewed from above the plane (e.g., in a plan view), the distance between the second light receiving layer OPD2 and the first-second transistor T1-2 may be greater than the distance between the first light receiving layer OPD1 and the first-first transistor T1-1.

Because the second light receiving layer OPD2 is spaced apart from the first-second transistor T1-2, the first-second electrode AE1-2′ may extend toward the first-second transistor T1-2 in the second direction DR2, and may be connected to the first-second transistor T1-2 through the third-third contact hole CH3-3.

The first-first transistor T1-1 may be disposed in the first direction DR1 with respect to the second-first light emitting element OLED2-1. The first-second transistor T1-2 may be disposed in the first direction DR1 with respect to the second-fourth light emitting element OLED2-4.

FIG. 11 is a view illustrating the first light receiving element and the second light receiving element disposed in a planar region larger than that of the layout illustrated in FIG. 10J.

In FIG. 11, for convenience of illustration, the first and second light receiving layers OPD1 and OPD2, the first-first and first-second electrodes AE1-1′ and AE1-2′, the first and second connecting electrodes CNE2-2′ and CNE2-2, the first electrodes AE, and the emissive layers EML are illustrated, and the other components are omitted.

Referring to FIGS. 10J and 11, a connection point between the first connecting electrode CNE2-2′ and the first light receiving element LRE1 may be defined as a first connection point CPO1. The first connection point CPO1, which is a region overlapping with the third-third contact hole CH3-3′, may be defined as a connection point between the first connecting electrode CNE2-2′ and the first-first electrode AE1-1′.

A connection point between the second connecting electrode CNE2-2 and the second light receiving element LRE2 may be defined as a second connection point CPO2. In more detail, the second connection point CPO2, which is a region overlapping with the third-third contact hole CH3-3, may be defined as a connection point between the second connecting electrode CNE2-2 and the first-second electrode AE1-2′.

The first connecting electrode CNE2-2′ may extend from the first connection point CPO1 in the first direction DR1. The second connecting electrode CNE2-2 may extend from the second connection point CPO2 in the first direction DR1.

The second connecting electrode CNE2-2 may extend from the second connection point CPO2 in a direction opposite to the first direction DR1. Unlike the first connection point CPO1 and the first connecting electrode CNE2-2′, the second connecting electrode CNE2-2 may further extend from the second connection point CPO2 in the direction opposite to the first direction DR1. A first length L1 of the first connecting electrode CNE2-2′ and a second length L2 of the second connecting electrode CNE2-2 in the first direction DR1 may be equal to or substantially equal to each other.

Referring to FIGS. 10H and 11, a parasitic capacitor (hereinafter, referred to as the first parasitic capacitor) may be formed by the first connecting electrode CNE2-2′ and patterns disposed below the first connecting electrode CNE2-2′. A parasitic capacitor (hereinafter, referred to as the second parasitic capacitor) may be formed by the second connecting electrode CNE2-2 and patterns disposed below the second connecting electrode CNE2-2.

When the second connecting electrode CNE2-2 extends from the second connection point CPO2 in only the first direction DR1 and does not extend in the direction opposite to the first direction DR1, the length of the second connecting electrode CNE2-2 may be smaller than the length of the first connecting electrode CNE2-2′. In this case, a difference in a capacitance between the first parasitic capacitor and the second parasitic capacitor may be increased.

The first parasitic capacitor may affect operating characteristics of the first sensor SN1, and the second parasitic capacitor may affect operating characteristics of the second sensor SN2. As the difference in the capacitance between the first parasitic capacitor and the second parasitic capacitor is increased, a difference in a sensing sensitivity between the first sensor SN1 and the second sensor SN2 may be increased. In this case, sensing accuracy may be decreased.

In an embodiment of the present disclosure, the first length L1 of the first connecting electrode CNE2-2′ and the second length L2 of the second connecting electrode CNE2-2 may be equal to or substantially equal to each other, and thus, the capacitance of the first parasitic capacitor and the capacitance of the second parasitic capacitor may be similar to (e.g., the same or substantially the same as) each other. In this case, the difference in the sensing sensitivity between the first sensor SN1 and the second sensor SN2 may be decreased, and thus, the sensing accuracy may be improved.

The first length L1 of the first connecting electrode CNE2-2′ and the second length L2 of the second connecting electrode CNE2-2 may be equal to or substantially equal to each other. However, the present disclosure is not limited thereto. For example, when the second connecting electrode CNE2-2 extends from the second connection point CPO2 in the first direction DR1 and the direction opposite to the first direction DR1, and the difference in the sensing sensitivity between the first sensor SN1 and the second sensor SN2 is within an error level, the second length L2 of the second connecting electrode CNE2-2 may be different from the first length L1 of the first connecting electrode CNE2-2′.

Referring to FIGS. 10H and 11, based on the second direction DR2, the first distance DT1 between the first connection point CPO1 and the first light receiving layer OPD1 may be smaller than the second distance DT2 between the second connection point CPO2 and the second light receiving layer OPD2.

The first-first electrode AE1-1′ may extend from the first light receiving layer OPD1 in the second direction DR2, and the first-second electrode AE1-2′ may extend from the second light receiving layer OPD2 in the second direction DR2.

The first-first electrode AE1-1′ may further extend in the second direction DR2 past the first connection point CPO1. The first-first electrode AE1-1′ may extend in the second direction DR2, and may be disposed between the first-first and third-second light emitting elements OLED1-1 and OLED3-2, and between the second-second and second-third light emitting elements OLED2-2 and OLED2-3.

The first-second electrode AE1-2′ may extend to the second connection point CPO2 in the second direction DR2. The first-second electrode AE1-2′ may extend in the second direction DR2, and may be disposed between the first-second and third-first light emitting elements OLED1-2 and OLED3-1, and between the second-first and second fourth light emitting elements OLED2-1 and OLED2-4.

Unlike the first-second electrode AE1-2′ and the second connection point CPO2, the first-first electrode AE1-1′ may further extend from the first connection point CPO1 in the second direction DR2. A third length L3 of the first-first electrode AE1-1′ and a fourth length L4 of the first-second electrode AE1-2′ in the second direction DR2 may be equal to or substantially equal to each other.

A parasitic capacitor (hereinafter, referred to as the third parasitic capacitor) may be formed by the first-first electrode AE1-1′ and patterns disposed below the first-first electrode AE1-1′. A parasitic capacitor (hereinafter, referred to as the fourth parasitic capacitor) may be formed by the first-second electrode AE1-2′ and patterns disposed below the first-second electrode AE1-2′.

When the first-first electrode AE1-1′ does not further extend from the first connection point CPO1 in the second direction DR2, the length of the first-second electrode AE1-2′ may be greater than the length of the first-first electrode AE1-1′. In this case, a difference in a capacitance between the third parasitic capacitor and the fourth parasitic capacitor may be increased.

The third and fourth parasitic capacitors may affect operating characteristics of the first and second sensors SN1 and SN2. As the difference in the capacitance between the third parasitic capacitor and the fourth parasitic capacitor is increased, a difference in a sensing sensitivity between the first sensor SN1 and the second sensor SN2 may be increased, and therefore, sensing accuracy may be decreased.

In an embodiment of the present disclosure, as the third length L3 of the first-first electrode AE1-1′ and the fourth length L4 of the first-second electrode AE1-2′ in the second direction DR2 are equal to or substantially equal to each other, the capacitance of the third parasitic capacitor and the capacitance of the fourth parasitic capacitor may be similar to (e.g., the same or substantially the same as) each other. In this case, the difference in the sensing sensitivity between the first sensor SN1 and the second sensor SN2 may be decreased, and thus, the sensing accuracy may be improved.

The third length L3 of the first-first electrode AE1-1′ and the fourth length L4 of the first-second electrode AE1-2′ may be equal to or substantially equal to each other. However, the present disclosure is not limited thereto. For example, when the first-first electrode AE1-1′ further extends in the second direction DR2 than the first connection point CPO1, and the difference in the sensing sensitivity between the first sensor SN1 and the second sensor SN2 is within an error level, the third length L3 of the first-first electrode AE1-1′ may be different from the fourth length L4 of the first-second electrode AE1-2′.

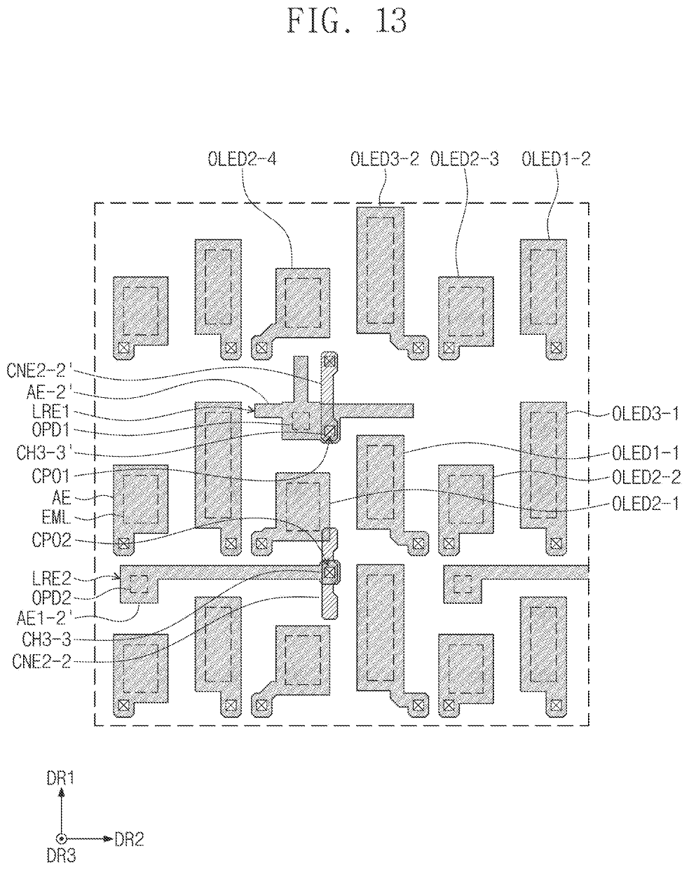

FIGS. 12 through 14 are views illustrating configurations of first-first electrodes according to embodiments of the present disclosure.

FIGS. 12 through 14 are plan views corresponding to FIG. 11. Hereinafter, the differences between the first-first electrode AE1-1′ illustrated in FIG. 11 and the first-first electrodes 1-1 illustrated in FIGS. 12 through 14 may be mainly described, and redundant description may not be repeated.

Referring to FIG. 12, a first-first electrode AE-1′ may further extend in the second direction DR2 than (e.g., past) the first connection point CPO1. In addition, the first-first electrode AE-1′ may further extend from the first light receiving layer OPD1 in a direction opposite to the second direction DR2.

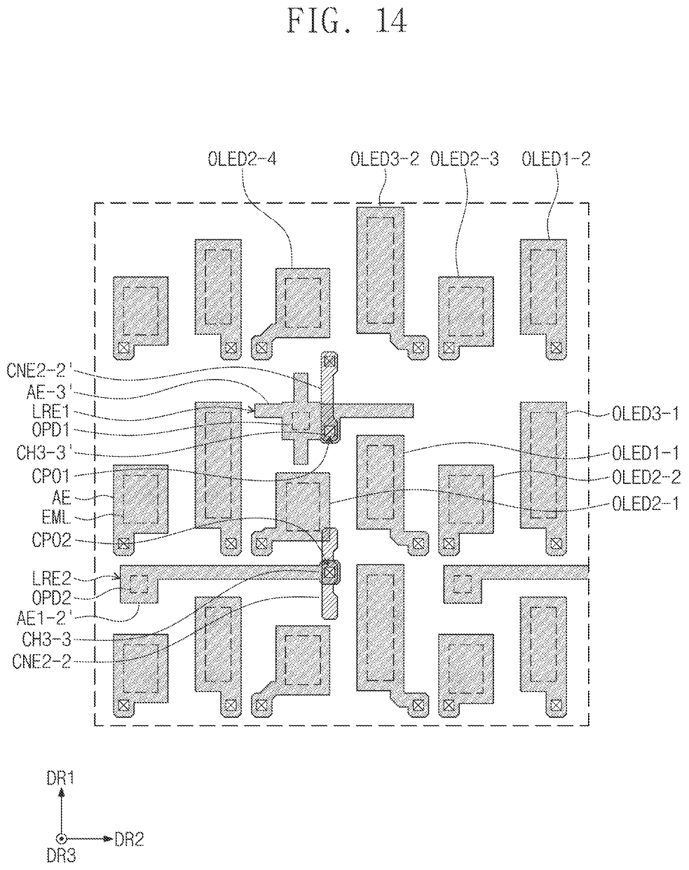

Referring to FIG. 13, a first-first electrode AE-2′ may further extend in the second direction DR2 than (e.g., past) the first connection point CPO1. In addition, the first-first electrode AE-2′ may further extend from the first light receiving layer OPD1 in the first direction DR1, and in the direction opposite to the second direction DR2.

Referring to FIG. 14, a first-first electrode AE-3′ may further extend in the second direction DR2 than (e.g., past) the first connection point CPO1. In addition, the first-first electrode AE-3′ may further extend from the first light receiving layer OPD1 in the first direction DR1, in the direction opposite to the first direction DR1, in the second direction DR2, and in the direction opposite to the second direction DR2.

Portions of the first-first electrode AE-3′ that extend from the first light receiving layer OPD1 in the first direction DR1, in the direction opposite to the first direction DR1, in the second direction DR2, and in the direction opposite to the second direction DR2 may have the same or substantially the same width as each other. A width may be defined as a numerical value measured in a direction crossing an extension direction of a corresponding component.

According to various embodiments of the present disclosure, the sensing part may include the first and second sensors that are imbedded in the display panel to sense a fingerprint. The first connecting electrode that connects the first-first transistor and the first-first electrode of the first sensor to each other and the second connecting electrode that connects the first-second transistor and the first-second electrode of the second sensor to each other may have the same or substantially the same length as each other. In addition, the first-first electrode and the first-second electrode may have the same or substantially the same length as each other.

Accordingly, the capacitances of the parasitic capacitors formed by the first and second connecting electrodes may be similar to (e.g., may be the same or substantially the same as) each other, and the capacitances of the parasitic capacitors formed by the first-first and first-second electrodes may be similar to (e.g., may be the same or substantially the same as) each other. Thus, a sensing deviation between the first sensor and the second sensor may be decreased, so that the sensing accuracy may be improved.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a first pixel unit comprising a first sensor; and
a second pixel unit comprising a second sensor,
wherein the first sensor comprises:
a first light receiving element;
a first-first transistor connected to the first light receiving element; and
a first connecting electrode connecting the first light receiving element to the first-first transistor, and extending in a first direction from a first connection point with the first light receiving element, and
wherein the second sensor comprises:
a second light receiving element;
a first-second transistor connected to the second light receiving element; and
a second connecting electrode connecting the second light receiving element to the first-second transistor, and extending in the first direction and a direction opposite to the first direction from a second connection point with the second light receiving element.

2. The display device of claim 1, wherein a length of the first connecting electrode and a length of the second connecting electrode are equal to each other.

3. The display device of claim 1, wherein a length of the first connecting electrode and a length of the second connecting electrode are different from each other.

4. The display device of claim 1,
wherein the first light receiving element comprises:
a first-first electrode connected to a gate electrode of the first-first transistor through the first connecting electrode;
a second electrode over the first-first electrode; and
a first light receiving layer between the first-first electrode and the second electrode of the first light receiving element, and
wherein the second light receiving element comprises:
a first-second electrode connected to a gate electrode of the first-second transistor through the second connecting electrode;
a second electrode over the first-second electrode; and
a second light receiving layer between the first-second electrode and the second electrode of the second light receiving element.

5. The display device of claim 4, wherein in a second direction crossing the first direction, a distance between the first connection point and the first light receiving layer is smaller than a distance between the second connection point and the second light receiving layer.

6. The display device of claim 5, wherein the first-first electrode extends from the first light receiving layer in the second direction, and further extends in the second direction than the first connection point.

7. The display device of claim 6, wherein the first-second electrode extends in the second direction, and extends from the second light receiving layer to the second connection point.

8. The display device of claim 7, wherein a length of the first-first electrode and a length of the first-second electrode are equal to each other.

9. The display device of claim 1, wherein a length of the first-first electrode and a length of the first-second electrode are different from each other.

10. The display device of claim 6, wherein the first-first electrode further extends from the first light receiving layer in a direction opposite to the second direction.

11. The display device of claim 10, wherein the first-first electrode further extends from the first light receiving layer in the first direction.

12. The display device of claim 11, wherein the first-first electrode further extends from the first light receiving layer in the direction opposite to the first direction.

13. The display device of claim 12, wherein portions of the first-first electrode extending from the first light receiving layer in the first direction, the second direction, the direction opposite to the first direction, and the direction opposite to the second direction have the same width as each other.

14. The display device of claim 1, wherein the first pixel unit and the second pixel unit are located along a first diagonal direction, and
wherein the first diagonal direction crosses the first direction and a second direction crossing the first direction on a plane defined by the first direction and the second direction.

15. The display device of claim 14, wherein the first pixel unit further comprises:
a third-first light emitting element;
a second-first light emitting element;
a first-first light emitting element; and
a second-second light emitting element configured to display the same color as that of the second-first light emitting element,
wherein the third-first light emitting element, the second-first light emitting element, the first-first light emitting element, and the second-second light emitting element are sequentially located along the second direction, and
wherein the first light receiving element is adjacent to the second-first light emitting element in the first direction.

16. The display device of claim 15, wherein the second pixel unit comprises:
a third-second light emitting element;
a second-third light emitting element;
a first-second light emitting element; and
a second-fourth light emitting element configured to display the same color as that of the second-third light emitting element,
wherein the third-second light emitting element, the second-third light emitting element, the first-second light emitting element, and the second-fourth light emitting element are sequentially located along the second direction, and
wherein:
the first-first light emitting element and the third-second light emitting element are located along the first direction;
the second-second light emitting element and the second-third light emitting element are located along the first direction; and
the second light receiving element is located between the second-second light emitting element and the second-third light emitting element.

17. The display device of claim 16, wherein the first-first transistor is spaced from the second-first light emitting element in the first direction, and
wherein the first-second transistor is spaced from the second-fourth light emitting element in the first direction.

18. A sensing part comprising:
a first sensor; and
a second sensor located along a diagonal direction with the first sensor,
wherein the first sensor comprises:
a first light receiving element;
a first-first transistor connected to the first light receiving element; and
a first connecting electrode connecting the first light receiving element to the first-first transistor, and extending in a first direction from a first connection point with the first light receiving element, and
wherein the second sensor comprises:
a second light receiving element;
a first-second transistor connected to the second light receiving element; and
a second connecting electrode connecting the second light receiving element to the first-second transistor, and extending in the first direction and a direction opposite to the first direction from a second connection point with the second light receiving element.

19. A display device comprising:
a plurality of pixels; and
a first sensor and a second sensor located between the pixels,
wherein the first sensor comprises:
a first light receiving element;
a first-first transistor; and
a first connecting electrode connecting the first light receiving element to the first-first transistor, and extending in a first direction,
wherein the second sensor comprises:
a second light receiving element;
a first-second transistor; and
a second connecting electrode connecting the second light receiving element to the first-second transistor, and extending in the first direction,
wherein the first light receiving element comprises:
a first-first electrode;
a second electrode; and
a first light receiving layer between the first-first electrode and the second electrode of the first light receiving element,
wherein the second light receiving element comprises:
a first-second electrode;
a second electrode; and
a second light receiving layer between the first-second electrode and the second electrode of the second light receiving element, and
wherein the first-first electrode extends from the first light receiving layer in a second direction crossing the first direction, and further extends in the second direction than the first connecting electrode and a first connection point of the first-first electrode.

20. The display device of claim 19, wherein the first-second electrode extends from the second light receiving layer to the second connecting electrode and a second connection point of the first-second electrode in the second direction, and
wherein a length of the first-first electrode is equal to a length of the first-second electrode.
